(19) United States
(12) Patent Application Publication
(10) Pub. No.: US 2026/0262221 A1
(43) Pub. Date: Sep. 3, 2026

(54) SEMICONDUCTOR STORAGE AND METHOD FOR MANUFACTURING THE SAME

(71) Applicant: Kioxia Corporation, Tokyo (JP)

(72) Inventor: Kosei NODA, Yokkaichi Mie (JP)

(73) Assignee: Kioxia Corporation, Tokyo (JP)

(21) Appl. No.: 19/328,263

(22) Filed: Sep. 15, 2025

(30) Foreign Application Priority Data
Feb. 28, 2025 (JP) 2025-031857

(51) Int. Cl. H10B 43/27; H10B 43/10; H10B 43/35

(52) U.S. Cl. CPC H10B 43/27; H10B 43/10; H10B 43/35

(57) ABSTRACT

A semiconductor storage includes: a first area that includes first conductive layers and semiconductor pillars; a second area that includes second conductive layers and semiconductor pillars; and a third area that includes third conductive layers and connects to one first conductive layer and one second conductive layer, the third area including a fourth area that electrically connects one first conductive layer and one second conductive layer and a fifth area in which one third conductive layer is connected to a contact, the fifth area including a tilted step portion that includes the third conductive layers stacked stepwise and a plurality of slit members that divide the area, some of the slit members are at positions where the fifth area is divided, the slit member includes intermittent portions that are on both sides of the slit member and communicate with the fifth area and bridging portions that fill the intermittent portions.

### CROSS-REFERENCE TO RELATED APPLICATION

This application is based upon and claims the benefit of priority from Japanese Patent Application No. 2025-031857, filed Feb. 28, 2025, the entire contents of which are incorporated herein by reference.

### FIELD

Embodiments described herein relate generally to a semiconductor storage and a method for manufacturing the same.

### BACKGROUND

In recent years, semiconductor devices including three-dimensionally integrated memory cells have been proposed. In such a semiconductor device, through holes are formed on a stacked body in which insulating layers and conductive layers are alternately stacked, and a memory layer and a silicon layer that can store charge are formed on the inner surface of the through hole, so that memory cells are formed between the silicon layer and the conductive layer.

Furthermore, a semiconductor storage including memory cells has a known structure in which a contact electrode is connected to a conductive layer of a stacked body.

### BRIEF DESCRIPTION OF THE DRAWINGS

FIG. 1 is a block diagram showing an example of the configuration of a memory system including a semiconductor storage according to a first embodiment.

FIG. 2 is a circuit diagram showing an example of the circuit configuration of a memory cell array provided in the semiconductor storage.

FIG. 3 is a perspective view showing an example of the appearance of the semiconductor storage.

FIG. 4 is a perspective view showing the outline of the bonding structure of the semiconductor storage.

FIG. 5 is a schematic plan view showing an example of the planar layout of memory areas and a lead-out area of the memory cell array.

FIG. 6 is a plan view showing an example of a planar layout in the memory area.

FIG. 7 is a cross-sectional view taken along line VII-VII of FIG. 6, showing an example of a cross-sectional structure in the memory area.

FIG. 8 is a cross-sectional view taken along line VIII-VIII of FIG. 6, showing an example of the cross-sectional structure of a pillar provided in the memory area.

FIG. 9 is a plan view showing an example of a planar layout in the memory areas and the lead-out area.

FIG. 10 is a perspective view showing a contact connected to a tilted step portion.

FIG. 11A is a cross-sectional view taken along line XIA-XIA of FIG. 9.

FIG. 11B is a cross-sectional view taken along line XIB-XIB of FIG. 9.

FIG. 12 is a diagram showing a cross-sectional structure when the memory area has a three-layer structure.

FIG. 13A is an explanatory drawing showing a state in which a first layer area is formed in the tilted step portion formed when the lead-out area has a three-layer structure.

FIG. 13B is an explanatory drawing showing a state in which a second layer area is formed in the tilted step portion formed when the lead-out area has a three-layer structure.

FIG. 13C is an explanatory drawing showing a state in which a third layer area is formed in the tilted step portion formed when the lead-out area has a three-layer structure.

FIG. 14A is an explanatory drawing showing a second embodiment when the lead-out area has a three-layer structure.

FIG. 14B is an explanatory drawing showing a third embodiment when the lead-out area has a three-layer structure.

FIG. 14C is an explanatory drawing showing a fourth embodiment when the lead-out area has a three-layer structure.

FIG. 14D is an explanatory drawing showing a fifth embodiment when the lead-out area has a three-layer structure.

FIG. 15A is an explanatory drawing showing an example of a manufacturing method of the lead-out area according to the first embodiment.

FIG. 15B is an explanatory drawing showing an example of the manufacturing method of the lead-out area according to the first embodiment.

FIG. 15C is an explanatory drawing showing an example of the manufacturing method of the lead-out area according to the first embodiment.

FIG. 16A is a cross-sectional view showing an example of the manufacturing method when the lead-out area has a three-layer structure.

FIG. 16B is a cross-sectional view showing the example of the manufacturing method when the lead-out area has a three-layer structure.

FIG. 16C is a cross-sectional view showing the example of the manufacturing method when the lead-out area has a three-layer structure.

FIG. 17 is an explanatory drawing showing the structure of the lead-out area according to a sixth embodiment.

FIG. 18 is an explanatory drawing showing the structure of the lead-out area according to a seventh embodiment.

FIG. 19A is an explanatory drawing showing the structure of the lead-out area according to an eighth embodiment.

FIG. 19B is a plan view showing the structure of the lead-out area according to the eighth embodiment.

FIG. 19C is a plan view showing the structure of the lead-out area according to the eighth embodiment.

FIG. 20A is a plan view showing the structure of the lead-out area according to a ninth embodiment.

FIG. 20B is a cross-sectional view showing the structure of the lead-out area according to the ninth embodiment.

### DETAILED DESCRIPTION

One or more embodiments may provide a semiconductor storage and a method for manufacturing the same, the semiconductor storage having a stacked structure with a well-formed shape by suppressing deformation of a tilted step portion and a stacked structure located around the tilted step portion in a semiconductor device including the tilted step portion having a plurality of conductive layers arranged stepwise with a connected contact.

In general, according to one embodiment, the semiconductor storage according to the embodiment includes a first area that includes a plurality of first conductive layers stacked at certain intervals in a first direction and first semiconductor pillars extending in the first direction in the plurality of first conductive layers and has memory cells formed at intersections between the plurality of first conductive layers and the first semiconductor pillars. The semiconductor storage includes a second area that includes a plurality of second conductive layers stacked at certain intervals and second semiconductor pillars extending in the first direction in the plurality of second conductive layers and has memory cells formed at intersections between the plurality of second conductive layers and the second semiconductor pillars. The semiconductor storage includes a third area that includes a plurality of third conductive layers stacked at certain intervals such that the third area is disposed between the first area and the second area and one of the third conductive layers connects to one of the first conductive layers and one of the second conductive layers. The third area includes a fourth area in which one of the third conductive layers electrically connects one of the first conductive layers and one of the second conductive layers, and a fifth area in which one of the third conductive layers is connected to a contact. The third area includes a tilted step portion where the third conductive layers are partially stacked stepwise in the fifth area. Furthermore, a plurality of unit areas are provided, each of the unit areas including the first area, the second area, and the third area, and a plurality of slit members are provided, the slit members dividing the unit areas into individual areas. Among the plurality of slit members, Some of the slit members are formed at positions where the fifth area is divided, and, some of the slit members include intermittent portions that are located at both sides of the slit member in a width direction and communicate with the fifth area, and include bridging portions filling the intermittent portions.

A semiconductor storage according to embodiments will be specifically described below with reference to the accompanying drawings. The following drawings are schematic, and the dimensions and proportions of the drawings are not necessarily the same as those in reality.

Hereinafter, components having substantially the same functions and configurations are indicated by the same reference numerals. In the following description, “connection” of a first element to a second element includes connection of the first element at all times or selectively to the second element indirectly via a conductive intermediate element or directly to the second element without the intermediate element.

### (First Embodiment)

A semiconductor storage according to a first embodiment will be described below. The semiconductor storage is, for example, a nonvolatile semiconductor storage (semiconductor memory) in which a plurality of memory cells are arranged in three-dimensional directions.

### 1.1 Configuration

### 1.1.1 Memory System

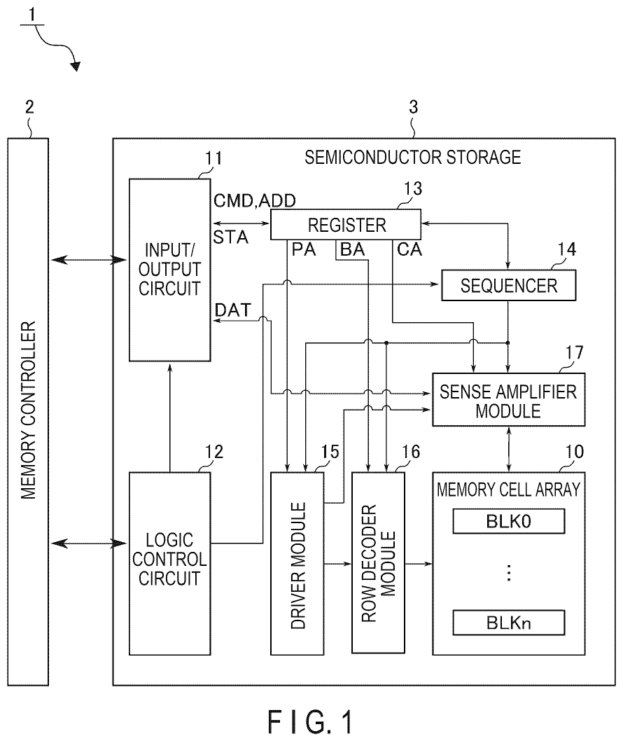

The semiconductor storage according to the first embodiment will be described below. FIG. 1 is a block diagram illustrating an example of the configuration of a memory system according to the first embodiment. A memory system 1 is a storage device configured to be connected to an external host device (not shown). The memory system 1 is, for example, a memory card such as an SDTM card, a universal flash storage (UFS), or a solid state drive (SDD). The memory system 1 includes a memory controller 2 and a semiconductor storage 3.

The memory controller 2 is composed of, for example, an integrated circuit such as a system-on-a-chip (SoC). The memory controller 2 controls the semiconductor storage 3 on the basis of a request from an external host device. Specifically, the memory controller 2 writes data requested to be written by the external host device to the semiconductor storage 3. Moreover, the memory controller 2 reads data requested to be read by the external host device from the semiconductor storage 3, and then the memory controller 2 outputs the data to the external host device.

The semiconductor storage 3 is, for example, a NAND flash memory in which data can be stored with nonvolatility.

Communications between the memory controller 2 and the semiconductor storage 3 are in conformity with, for example, a single data rate (SDR) interface, a toggle double data rate (DDR) interface, or an open NAND flash interface (ONFI).

### 1.1.2 Semiconductor Storage

Hereinafter, referring to the block diagram shown in FIG. 1, the internal configuration of the semiconductor storage 3 according to the first embodiment will be described. The semiconductor storage 3 includes, for example, a memory cell array 10, an input/output circuit 11, a logic control circuit 12, a register 13, a sequencer 14, a driver module 15, a row decoder module 16, and a sense amplifier module 17.

The memory cell array 10 is a collection of sets of memory cell transistors and components connected to the memory cell transistors. The memory cell array 10 includes a plurality of blocks (unit areas) BLK0 to BLKn (n is an integer equal to or larger than 1). The block BLK is a set of memory cell transistors that can store data with nonvolatility. The block BLK is used as an erasure unit for erasing data stored by the memory cell transistors, for example. Furthermore, the memory cell array 10 includes a plurality of bit lines and a plurality of word lines. Each of the memory cell transistors is associated with, for example, a combination of a bit line and a word line. The configuration of the memory cell array 10 will be described in detail later.

The input/output circuit 11 is an interface circuit that controls transmission and reception of an input/output signal to and from the memory controller 2. The input/output signal includes, for example, data DAT, a command CMD, address information ADD, and status information STA. The input/output circuit 11 inputs and outputs the data DAT between the sense amplifier module 17 and the memory controller 2. The input/output circuit 11 outputs the command CMD and the address information ADD, which are transferred from the memory controller 2, to the register 13. The input/output circuit 11 outputs the status information STA transferred from the register 13, to the memory controller 2.

The logic control circuit 12 receives a control signal input from the memory controller 2. The logic control circuit 12 controls the input/output circuit 11 and the sequencer 14 on the basis of the control signal. For example, the logic control circuit 12 notifies the input/output circuit 11 that the input/output signal received by the input/output circuit 11 is the command CMD, the address information ADD or the like. The logic control circuit 12 instructs the input/output circuit 11 to input or output the input/output signal. The logic control circuit 12 controls the sequencer 14 to enable the semiconductor storage 3. Furthermore, the logic control circuit 12 outputs, to the memory controller 2, a signal indicating whether the semiconductor storage 3 is placed in a ready state or a busy state.

The register 13 temporarily stores the command CMD, the address information ADD, and the status information STA. The command CMD includes, for example, commands for causing the sequencer 14 to execute a reading operation, a writing operation, and an erasing operation. The address information ADD includes, for example, a block address BA, a page address PA, and a column address CA. For example, the block address BA, the page address PA, and the column address CA are used for selecting, the block BLK, the word line, and the bit line, respectively. The status information STA is updated on the basis of the control of the sequencer 14 and is transferred to the input/output circuit 11.

The sequencer 14 controls the overall operations of the semiconductor storage 3. For example, the sequencer 14 controls the driver module 15, the row decoder module 16, the sense amplifier module 17 or the like on the basis of the command CMD stored in the register 13 and performs a reading operation, a writing operation, an erasing operation or the like.

The driver module 15 generates a plurality of voltages of different magnitudes used for, for example, a reading operation, a writing operation, and an erasing operation. The driver module 15 supplies the generated voltages to, for example, the row decoder module 16 and the sense amplifier module 17. In addition, the driver module 15 applies the generated voltage to the signal line corresponding to the word line selected on the basis of the page address PA stored in the register 13, for example.

For example, on the basis of the block address BA stored in the register 13, the row decoder module 16 selects corresponding one of the blocks BLK in the memory cell array 10. The row decoder module 16 transfers, for example, the voltage of the signal line to the selected word line in the selected block BLK, the voltage being applied by the driver module 15.

The sense amplifier module 17 includes a sense amplifier that can determine data on the basis of the voltage of the associated bit line, and a latch circuit that temporarily stores data. The sense amplifier module 17 applies, in a writing operation, a desired voltage to each of the bit lines according to the write data DAT received from the input/output circuit 11. Moreover, in a reading operation, the sense amplifier module 17 determines data stored in the memory cell transistor on the basis of the magnitude of the voltage of the bit line. Thereafter, the sense amplifier module 17 reads the determination result and transfers the result as the data DAT to the input/output circuit 11.

### 1.1.3 Circuit Configuration of Memory Cell Array

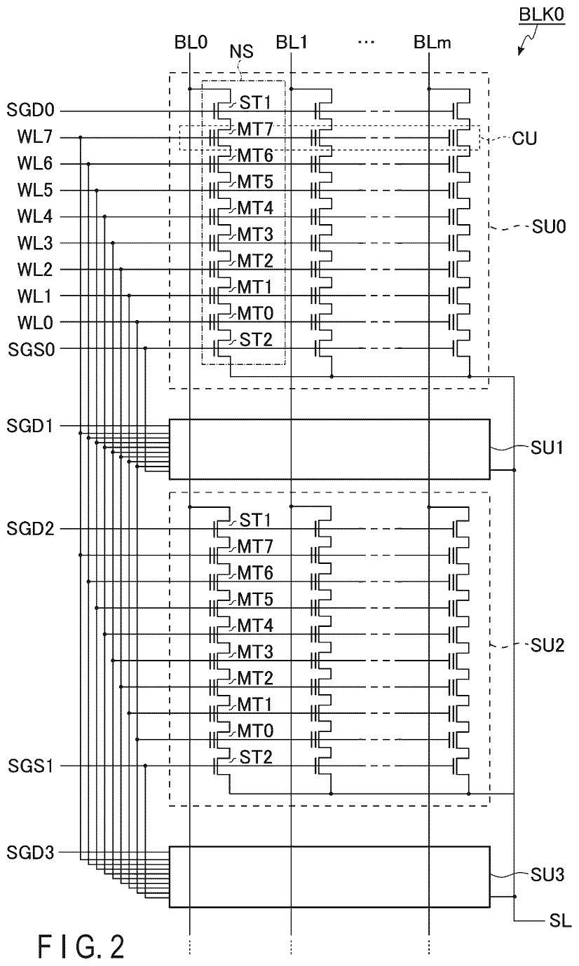

FIG. 2 is a circuit diagram showing an example of the circuit configuration of the memory cell array provided in the semiconductor storage according to the first embodiment. FIG. 2 shows the block BLK0. The block BLK0 includes, for example, four string units SU0 to SU3.

The string units SU each include a plurality of NAND strings NS associated with respective bit lines BL0 to BLm (m is an integer equal to or larger than 1). The NAND strings NS each include, for example, eight memory cell transistors MT0 to MT7 and select transistors ST1 and ST2. The memory cell transistors MT each include a control gate and a charge storage film and store data with nonvolatility according to the amount of charge in the charge storage film. Each of the select transistors ST1 and ST2 is used for selecting the string units SU during various operations.

In each of the NAND strings NS, the memory cell transistors MT0 to MT7 are connected in series in this order. The drain of the select transistor ST1 is connected to the associated bit line BL, and the source of the select transistor ST1 is connected to the drain of the memory cell transistor MT7. The drain of the select transistor ST2 is connected to the source of the memory cell transistor MT0, and the source of the select transistor ST2 is connected to a source line SL.

The control gates of the memory cell transistors MT0 to MT7 in the same block BLK are connected to word lines WL0 to WL7, respectively. The gates of the select transistors ST1 in the string units SU0 to SU3 are connected to corresponding select gate lines SGD0 to SGD3. The gates of the select transistors ST2 in the string units SU0 and SU1 are each connected to a select gate line SGS0. The gates of the select transistors ST2 in the string units SU2 and SU3 are each connected to a select gate line SGS1.

The different column addresses CA are allocated to the respective bit lines BL0 to BLm. The bit line BL is shared by the NAND strings NS to which the same column address CA is allocated among the blocks BLK. The word lines WL0 to WL7 are provided in each of the blocks BLK. The source line SL is shared among the blocks BLK, for example.

For example, a set of the memory cell transistors MT connected to the common word line WL in one of the string units SU is referred to as a cell unit CU. For example, the storage capacity of the cell unit CU including the memory cell transistors MT, each of which stores one bit of data, is defined as “one-page data”. The cell unit CU may have a storage capacity of two-page data or more according to the number of bits of data stored in the memory cell transistor MT.

Note that the circuit configuration of the memory cell array 10 provided in the semiconductor storage 3 according to the first embodiment is not limited to that of the foregoing description. For example, the number of string units SU included in each of the blocks BLK may be set to any number. However, the number of string units SU included in each of the blocks BLK is desirably an even number. The number of memory cell transistors MT included in each of the NAND strings NS and the number of select transistors ST1 and ST2 may be set to any number.

The following example describes a structure including seven memory cell transistors MT as shown in FIG. 2 as an example.

### 1.1.4 Appearance of Semiconductor Storage

The semiconductor storage 3 according to the first embodiment is formed by bonding two semiconductor circuit boards, each of which has a semiconductor circuit, and separating the bonded semiconductor circuit boards into chips. That is, the semiconductor storage 3 according to the first embodiment includes a structure formed by bonding semiconductor substrates W1 and W2. The semiconductor substrates W1 and W2 are, for example, silicon substrates.

In the following description, the semiconductor substrate W2 is removed in the manufacturing process of the semiconductor storage 3 will be described. Note that depending on the structure of the memory cell array 10, the semiconductor substrate W2 may be partially left after bonding.

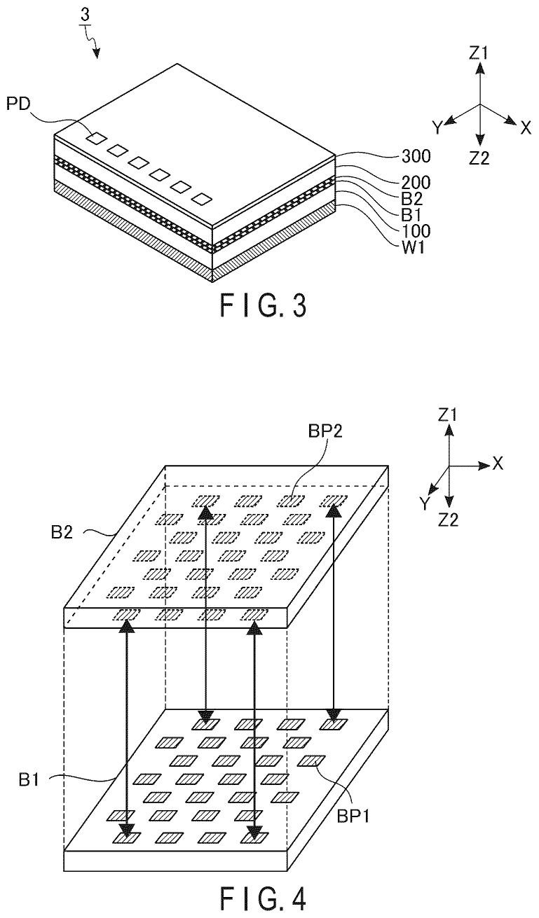

FIG. 3 is a perspective view illustrating an example of the appearance of the semiconductor storage according to the first embodiment. In FIG. 3, hatching is added to increase the visibility of the drawing but is not necessarily associated with the materials or characteristics of the hatched components. As shown in FIG. 3, the semiconductor storage 3 has a structure in which the semiconductor substrate W1, a control circuit layer 100, a bonding layer B1, a bonding layer B2, a memory layer 200, and a wiring layer 300 are stacked in this order, for example.

In the following description, a plane where the semiconductor substrate W1 extends is referred to as an XY plane. Among the stacking directions of the stacked structure, the direction from the semiconductor substrate W1 to the wiring layer 300 is denoted as Z1 direction, and the direction from the wiring layer 300 to the semiconductor substrate W1 is denoted as Z2 direction. The Z1 direction and the Z2 direction are nearly perpendicular to the semiconductor substrate W1. Note that when the Z1 direction and the Z2 direction are not discriminated from each other, the Z1 direction and the Z2 direction are simply referred to as Z direction. The Z direction is also referred to as a first direction. Furthermore, in the description of X direction, +X direction and -X direction may be discriminated from each other. When the directions are not discriminated from each other, +X direction and −X direction may be simply referred to as X direction. The +X direction and −X direction will be described later. Also in the description of Y direction, +Y direction and −Y direction may be discriminated from each other. When the directions are not discriminated from each other, +Y direction and −Y direction may be simply referred to as Y direction. The +Y direction and -Y direction will be described later.

The control circuit layer 100 includes a control circuit formed by using the semiconductor substrate W1. The semiconductor substrate W1 includes an impurity diffusion area that corresponds to the design of the control circuit. The control circuit layer 100 includes, for example, the input/output circuit 11, the logic control circuit 12, the register 13, the sequencer 14, the driver module 15, the row decoder module 16, and the sense amplifier module 17.

The bonding layer B1 is formed by using the semiconductor substrate W1. The bonding layer B1 includes a plurality of bonding pads that are electrically connected to the control circuit provided in the control circuit layer 100 and form a part of the semiconductor circuit.

The bonding layer B2 is formed by using the semiconductor substrate W2 (not shown). The bonding layer B2 includes a plurality of bonding pads that are electrically connected to the memory cell array 10 provided in the memory layer 200 and form a part of the semiconductor circuit.

The memory layer 200 includes the memory cell array 10 formed by using the semiconductor substrate W2 (not shown).

The wiring layer 300 is formed after the semiconductor substrates W1 and W2 are bonded. The wiring layer 300 includes wiring connected to the semiconductor circuit provided in the memory layer 200 and a plurality of pads PD. The plurality of pads PD is exposed on the surface of the semiconductor storage 3. The pads PD are used for connecting the semiconductor storage 3 and the memory controller 2 or the like.

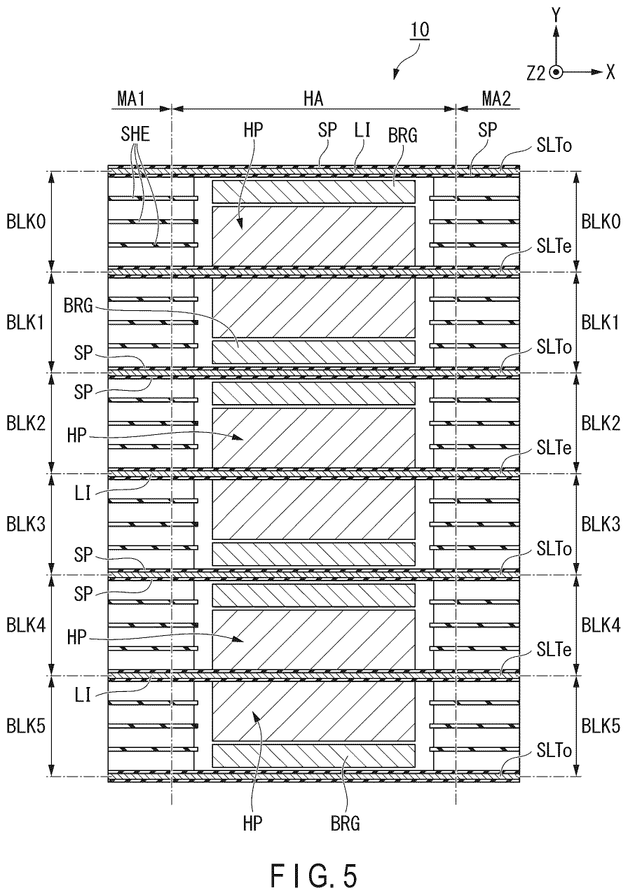

FIG. 4 is a perspective view illustrating the outline of the bonding structure of the semiconductor storage according to the first embodiment. Referring to FIG. 4, the bonding of the semiconductor substrates W1 and W2 will be described below.

As shown in FIG. 4, a plurality of bonding pads BP1 included in the bonding layer B1 and a plurality of bonding pads BP2 included in the bonding layer B2 are connected to each other. Thus, the control circuit provided in the control circuit layer 100 and the memory cell array 10 provided in the memory layer 200 are electrically connected to each other via the bonding pads BP1 and BP2. A portion between the bonding layers B1 and B2 corresponds to the boundary portion between the layer formed by using the semiconductor substrate W1 and the layer formed by using the semiconductor substrate W2 (not shown).

### 1.1.5 Structure of Memory Cell Array

An example of the structure of the memory cell array 10 provided in the semiconductor storage 3 according to the first embodiment will be described below. In the following description, the X direction corresponds to the extending direction of the word line WL. The Y direction corresponds to the extending direction of the bit line BL. The Z direction (first direction) is a direction orthogonal to the X direction and the Y direction. The Z direction is equal to the thickness direction of the semiconductor substrate W1. A plane extending in the X direction and the Z direction is referred to as an XZ plane. A plane extending in the Y direction and the Z direction is referred to as a YZ plane. In the plan view, hatching is added as appropriate to increase the visibility of the drawing. The hatching added to the plan view is not necessarily associated with the materials or characteristics of the hatched components. In the cross-sectional view, the illustration of the configuration is omitted as appropriate to increase the visibility of the drawing.

### 1.1.5.1 Summary

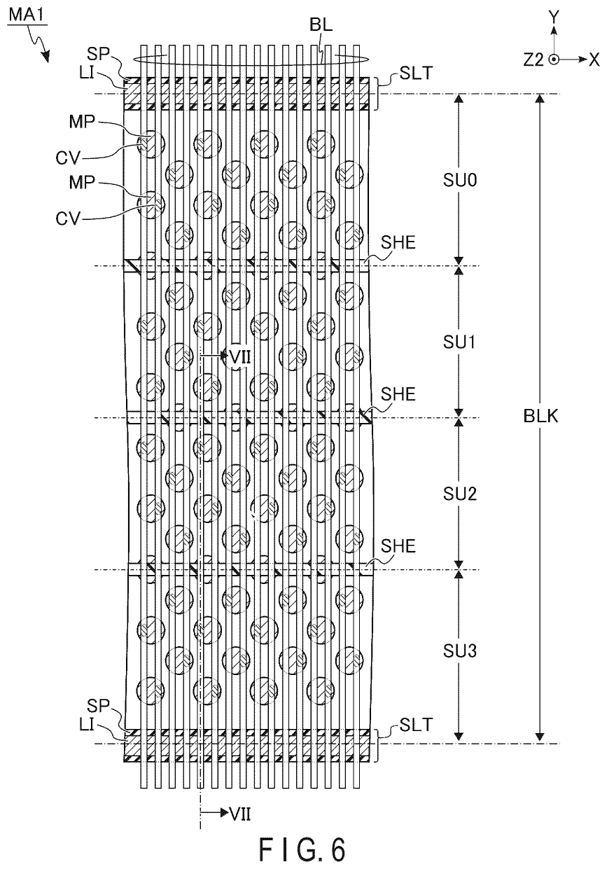

FIG. 5 is a plan view showing an example of the planar layout of the memory cell array provided in the semiconductor storage according to the first embodiment. FIG. 5 shows areas corresponding to the six blocks (unit areas) BLK0 to BLK5. The final numbers for discriminating the blocks BLK are serially assigned in ascending order from the top of the drawing. In the memory cell array 10, for example, the layout shown in FIG. 5 is repeatedly arranged in the Y direction. As shown in FIG. 5, the memory cell array 10 includes a plurality of slit members SLT and a plurality of slit portions SHE. The planar layout of the memory cell array 10 is divided into, for example, memory areas MA1 and MA2 and a lead-out area HA in the X direction. The lead-out area HA is provided between the memory area MA1 and the memory area MA2.

The memory areas MA1 and MA2 are areas that include the plurality of NAND strings NS (see FIG. 2) and are used for storing data. The lead-out area HA is an area used for connecting stacked wiring, in which multiple wiring layers (e.g., the word lines WL0 to WL7 and the select gate lines SGS0, SGS1, and SGD) are stacked at certain or predetermined intervals in the Z direction, and the row decoder module 16.

The slit members SLT extend along the X direction and are arranged in the Y direction. Each of the slit members SLT crosses the memory area MA1, the lead-out area HA, and the memory area MA2 in the X direction in a boundary area between the adjacent blocks BLK. In other words, each of the areas separated by the slit members SLT corresponds to one block (unit area) BLK in the memory cell array 10. For example, each of the slit members SLT has a structure in which spacers SP and a plate-like contact LI are embedded. Each of the slit members SLT separates the stacked wirings that are adjacent to each other with the slit member SLT interposed therebetween.

As shown in FIG. 5, in the present embodiment, the slit members SLT odd-numbered from the top of the drawing are referred to as “SLTo” and the even-numbered slit members SLT are referred to as “SLTe” among the slit members SLT arranged in the Y direction. In the memory cell array 10, pairs of slit members SLTo and slit members SLTe are arranged in the Y direction.

The slit portions SHE are located in each of the memory areas MA1 and MA2. The slit portions SHE corresponding to the memory area MA1 cross the memory area MA1 in the X direction and are arranged in the Y direction. The slit portions SHE corresponding to the memory area MA2 cross the memory area MA2 in the X direction and are arranged in the Y direction. In FIG. 5, the right ends of the slit portions SHE in the drawing corresponding to the memory area MA1 and the left ends of the slit portions SHE in the drawing corresponding to the memory area MA2 are included in the lead-out area HA. For example, in each of the memory areas MA1 and MA2, three slit portions SHE are located between the slit members SLT adjacent to each other in the Y direction. A combination of an area separated by the slit members SLT and the slit portions SHE of the memory area MA1 and an area separated by the slit members SLT and the slit portions SHE of the memory area MA2 corresponds to one of the string units SU in the memory cell array 10. For example, each of the slit portions SHE has a structure including an embedded insulator. Each of the slit portions SHE separates the select gate lines SGD that are adjacent to each other with the slit portion SHE interposed therebetween.

Note that the planar layout of the memory cell array 10 provided in the semiconductor storage 3 according to the first embodiment is not limited to the foregoing layout. For example, the number of slit portions SHE located between the adjacent slit members SLT may be set to any number. The number of string units SU formed between the adjacent slit members SLT may be changed on the basis of the number of slit portions SHE located between the adjacent slit members SLT. Note that the number of string units SU formed between the adjacent slit members SLT is desirably an even number. In other words, the number of slit portions SHE in each of the blocks BLK is desirably an odd number.

The lead-out area HA includes a plurality of lead-out portions HP. The lead-out portions HP each include a connection portion to a contact in each wiring layer of the stacked wiring. The lead-out portions HP are arranged in the Y direction and are provided for two blocks BLK adjacent to each other in the Y direction with the slit member SLTo interposed therebetween. The lead-out portions HP are each provided to be interposed between two slit members SLTo that hold two adjacent blocks BLK in the lead-out area HA. The lead-out portions HP are provided to be separated by two slit members SLTe that hold two adjacent blocks BLK in the lead-out area HA.

The lead-out area HA includes a plurality of bridge portions BRG. The bridge portion BRG is provided for each of the blocks BLK. In each of the bridge portions BRG, a portion provided in the memory area MA1 of each wiring layer of the stacked wiring and a portion provided in the memory area MA2 are connected to each other.

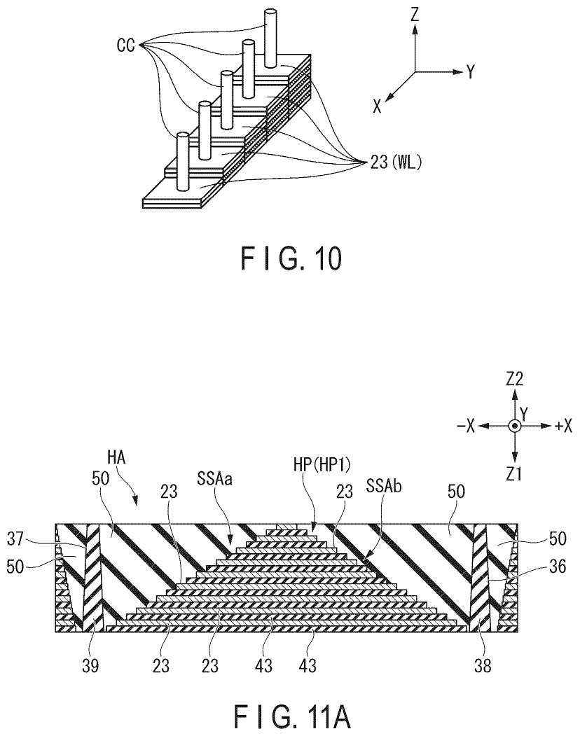

As shown in FIG. 5, the lead-out area HA is provided between the memory area MA1 and the memory area MA2 in the X direction. Each of the blocks BLK preferably includes a tilted step area SSA and the bridge portion BRG that are shown in FIG. 9 and other drawings.

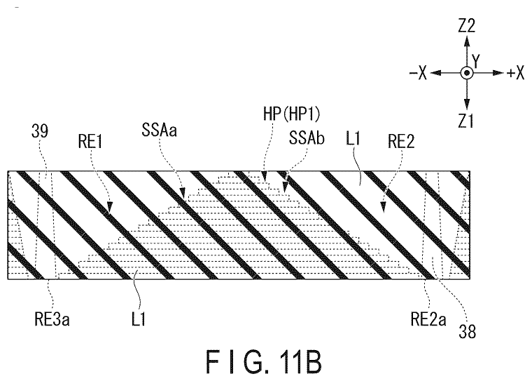

In the tilted step area SSA, the ends of the select gate lines (source-side select gates) SGS and the plurality of word lines WL are formed stepwise sequentially from the bottom layer in the X direction. In other words, in the tilted step area SSA, the select gate lines SGS and the plurality of word lines WL each have a terrace portion (also referred to as a step, a stepwise portion, or a lead-out portion) that does not overlap the wiring layer (conductive layer) of the bottom layer on the end. On each of the terrace portions, contacts CC shown in FIGS. 9 and 10 are formed as will be described later. Voltages may be applied separately to the select gate lines SGS and the plurality of word lines WL via the contacts CC. As described above, the tilted step area SSA is provided as a terrace area that connects the plurality of contacts to respective wiring layers 22 to 24 connected to the select gate lines SGS and the plurality of word lines WL. The wiring layers 22 to 24 will be described later.

Note that the contacts CC are electrically connected to a row decoder provided under the memory cell array. Thus, the row decoder can control the voltages of wiring layers 21 (word lines WL) through the contacts CC.

The planar layout of the memory cell array 10 provided in the semiconductor storage 3 according to the first embodiment is not limited to the foregoing layout. For example, the number of slit portions SHE located between the adjacent slit members SLT may be set to any number. The number of string units SU formed between the adjacent slit members SLT may be changed on the basis of the number of slit portions SHE located between the adjacent slit members SLT. Note that the number of string units SU formed between the adjacent slit members SLT is desirably an even number. In other words, the number of slit portions SHE in each of the blocks BLK is desirably an odd number.

### 1.1.5.2 Memory Area

### (Planar Layout)

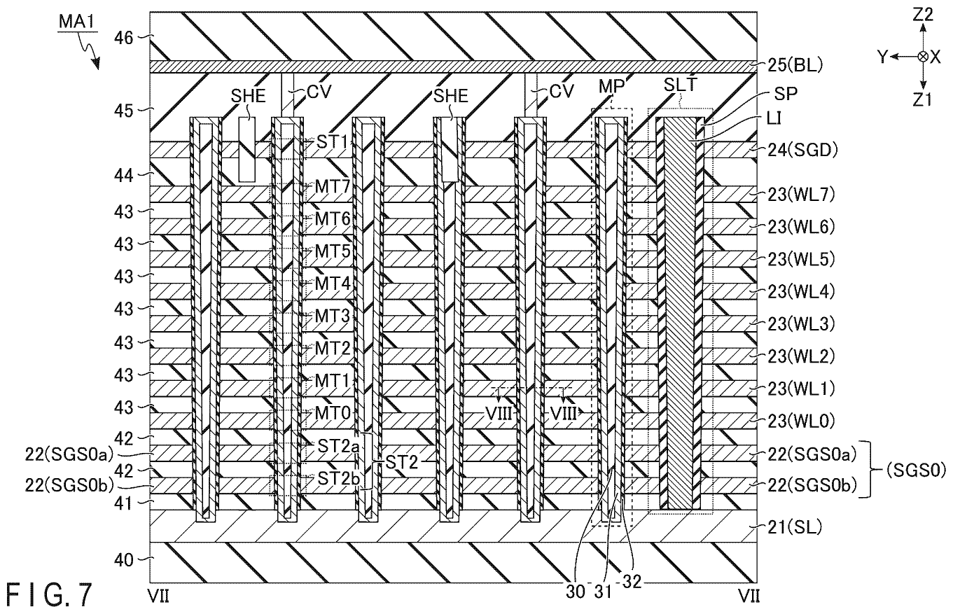

FIG. 6 is a plan view showing an example of a planar layout in the memory area of the memory cell array provided in the semiconductor storage according to the first embodiment. Note that FIG. 6 shows a representative structure of one block BLK in the memory area MA. As shown in FIG. 6, in the memory area MA1, the memory cell array 10 includes a plurality of pillars (memory pillars) MP, a plurality of contacts CV, and the plurality of bit lines BL. Moreover, each of the slit members SLT includes a contact LI and spacers SP on both sides of the contact LI in the thickness direction.

Each of the pillars MP functions as, for example, one of the NAND strings NS. The pillars MP are arranged in, for example, 19 rows of a staggered pattern in the Y direction in an area between two adjacent slit members SLT. In the example shown in FIG. 6, the slit portion SHE overlaps each of the pillars MP of the fifth, tenth, and fifteenth rows from the top of the drawing.

The bit lines BL extend in the Y direction and are arranged in the X direction. The bit lines BL are located to overlap at least one of the pillars MP in each of the string units SU. In the example shown in FIG. 6, two bit lines BL are located to overlap one of the pillars MP. When the multiple bit lines BL overlap the pillar MP, one of the bit lines BL and the corresponding pillar MP are electrically connected via the contact CV. Note that when one of the bit lines BL overlaps the pillar MP, the bit line BL and the corresponding pillar MP are electrically connected via the contact CV.

For example, the contact CV between the pillar MP in contact with the slit portion SHE and the corresponding bit line BL is omitted. In other words, the contact CV between the pillar MP in contact with two different select gate lines SGD and the bit line BL is omitted. The number and arrangement of pillars MP and slit portions SHE between the adjacent members SLT are not limited to the configuration shown in FIG. 6 and may be changed as appropriate. For example, the number of bit lines BL overlapping the pillars MP may be set to any number.

The contact LI is a conductor extending in an XZ plane. The undersurface of the contact LI is in contact with the source line SL that is not shown in the drawing. The spacers SP are insulators provided on the sides of the contact LI. In other words, the spacers SP are provided in contact with the contact LI so as to hold the contact LI in the Y direction.

### (Cross-sectional Structure)

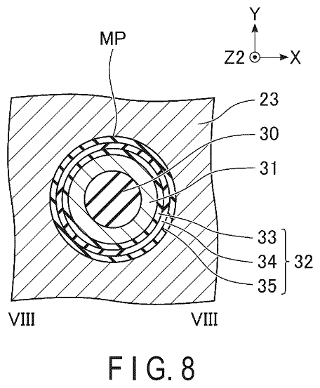

FIG. 7 is a cross-sectional view taken along line VII-VII of FIG. 6, showing an example of a cross-sectional structure in the memory area of the memory cell array provided in the semiconductor storage according to the first embodiment. As shown in FIG. 7, the memory cell array 10 further includes wiring layers 21 to 25, insulator layers 40 to 46, and the slit member SLT. In the following description, the Z2 direction may be referred to as an upward direction, and the Z1 direction may be referred to as a downward direction.

The stacked wiring included in the memory cell array 10 includes the wiring layers 22 corresponding to the select gate line SGS0, the plurality of wiring layers 23 corresponding to the word lines WL0 to WL7, and the wiring layer 24 corresponding to the select gate line SGD. Hereinafter, the select gate line may be simply denoted as the select gate line SGS.

In the example shown in FIG. 7, two wiring layers 22 corresponding to the select gate line SGS are provided.

In the following description, the select gate line SGS corresponding to the upper wiring layer 22 will be referred to as the select gate line SGS0a, and the select gate line SGS corresponding to the lower wiring layer 22 will be referred to as the select gate line SGS0b. The select gate lines SGS0a and SGS0b are connected to the gates of the select transistors ST2a and ST2b, respectively. The select transistors ST2a and ST2b function as the single select transistor ST2. Note that the select gate line SGS may correspond to the single wiring layer 22 or three or more wiring layers 22. When the multiple wiring layers 22 corresponding to the select gate line SGS are formed, the select transistors ST2a and ST2b may be configured to function independently. Alternatively, a select gate line SGS1a and a select gate line SGS1b may be further provided on the select gate line SGS0b as in the correspondence of FIG. 9. These select gate lines may be collectively denoted as the select gate line SGS1.

The insulator layer 41 is stacked above the semiconductor substrate (not shown), and the wiring layers 22 and the plurality of insulator layers 42 are alternately and sequentially stacked on the insulator layer 41. In the example shown in FIG. 7, two wiring layers 22 and two insulator layers 42 are alternately stacked. For example, the wiring layers 22 are formed like plates extending along the X direction on an XY plane. The wiring layers 22 are used as the select gate lines SGS0a and SGS0b. The wiring layers 22 contain, for example, tungsten (W) and molybdenum (Mo). The insulator layer 41 and the insulator layers 42 contain, for example, silicon oxide (SiO₂).

The wiring layers 23 and a plurality of insulator layers 43 are alternately stacked on the uppermost insulator layer 42. In the example shown in FIG. 7, eight wiring layers 23 and seven insulator layers 43 are alternately stacked. For example, the wiring layers 23 are formed like plates extending along the X direction on an XY plane. The wiring layers 23 are used sequentially as the word lines WL0 to WL7 from the wiring layer 22 side. The wiring layers 23 contain, for example, tungsten. The insulator layers 43 contain, for example, silicon oxide.

The insulator layer 44, the wiring layer 24, and the insulator layer 45 are stacked in this order on the uppermost wiring layer 23. For example, the wiring layer 24 is formed like a plate extending along the X direction on an XY plane. The wiring layer 24 is used as the select gate line SGD. The wiring layer 24 contains, for example, tungsten. The insulator layers 44 and 45 contain, for example, silicon oxide.

A wiring layer 25 is stacked on the insulator layer 45. For example, the wiring layer 25 is formed like a line extending along the Y direction. The wiring layer 25 is used as the bit line BL. In an area not shown in the drawing, the multiple wiring layers 25 are arranged along the X direction. The wiring layer 25 contains, for example, copper.

An insulator layer 46 is stacked on the wiring layer 25. The insulator layer 46 is a layer connected to the bonding layer B2 and includes a plurality of wirings that are not shown in the drawing.

In FIGS. 3 and 4, after the removal of the semiconductor substrate W2 not shown, the wiring layer 21 and the insulator layer 40 are provided in this order in the Z1 direction under the insulator layer 41. For example, the wiring layer 21 is formed like a plate extending along the X direction on an XY plane. The wiring layer 21 is used as the source line SL. The wiring layer 21 contains, for example, silicon doped with phosphorus. Furthermore, the wiring layer 300 shown in FIG. 3 may be provided under the insulator layer 40. The wiring layer 300 includes a plurality of wirings that not shown in the drawing.

The pillars MP are provided to extend along the Z direction (first direction). The pillars MP penetrate the wiring layers 22 to 24 and the insulator layers 41 to 44.

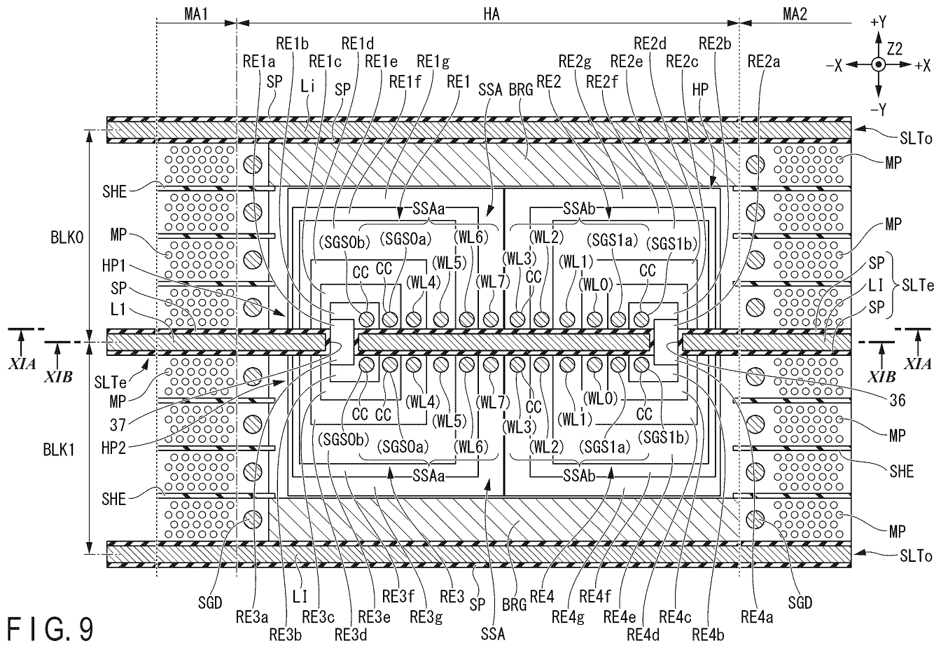

For example, as shown in FIG. 8, the pillar MP includes a core film 30, a semiconductor film 31, and a stacked film 32. In each of the pillars MP, the core film 30 is provided to extend along the Z direction. For example, the upper end of the core film 30 of the pillar MP3 is located in the insulator layer 45 and the lower end of the core film 30 of the pillar MP1 is located in the wiring layer 21. The core film 30 contains, for example, an insulator such as silicon oxide. The semiconductor film 31 covers, for example, the circumference of the core film 30. On the lower end of the pillar MP, the semiconductor film 31 is partially in contact with the wiring layer 21. The semiconductor film 31 contains, for example, silicon. The stacked film 32 covers the side of the semiconductor film 31 except for a contact portion between the semiconductor film 31 and the wiring layer 21.

FIG. 8 shows an example of a cross section of the pillar MP provided in the semiconductor storage according to the first embodiment. More specifically, FIG. 8 shows a cross-sectional structure of the pillar MP in a layer that is parallel with the surface of the semiconductor substrate, which is not shown, and includes the wiring layer 23. As shown in FIG. 8, the stacked film 32 includes, for example, a tunnel insulating film 33, a charge storage film 34, and a block insulating film 35.

In the cross section including the wiring layer 23, the core film 30 is provided at, for example, the central portion of the pillar MP. The semiconductor film 31 surrounds the side of the core film 30. The tunnel insulating film 33 surrounds the side of the semiconductor film 31. The charge storage film 34 surrounds the side of the tunnel insulating film 33. The block insulating film 35 surrounds the side of the charge storage film 34. The wiring layer 23 surrounds the side of the block insulating film 35. In the pillar MP, the core film 30, the semiconductor film 31, the tunnel insulating film 33, the charge storage film 34, and the block insulating film 35 are continuously extended from one end to the other end of the pillar MP in the Z direction.

The semiconductor film 31, the tunnel insulating film 33, the charge storage film 34, and the block insulating film 35 are formed with a predetermined thickness in the XY direction (second direction) that crosses the Z direction (first direction). Thus, in the second direction, the block insulating film 35 is provided on the wiring layers 23 and the insulator layers 43. Likewise, in the second direction, the charge storage film 34 is provided on the block insulating film 35. In the second direction, the tunnel insulating film 33 is provided on the charge storage film 34. In the second direction, the semiconductor film 31 is provided on the tunnel insulating film 33.

The semiconductor film 31 is used as a channel (current path) of the memory cell transistors MT0 to MT7 and the select transistors ST1 and ST2. The tunnel insulating film 33 and the block insulating film 35 contain, for example, silicon oxide. The charge storage film 34 has the function of storing charge and contains, for example, silicon nitride (SiN). This configuration allows the pillar MP to function as the single NAND string NS.

The pillar MP includes a memory cell serving as a nonvolatile semiconductor storage. The memory cell is, for example, a charge-trapping memory cell. The core film 30 functions as a channel-forming area.

The wiring layer 23 functions as the control gate of the memory cell.

The charge storage film 34 functions as a data storage layer that stores charge injected from the core film 30.

That is, at the intersection portion between the core film 30 and the wiring layer 23, the memory cell is formed with a structure including the control gate surrounding the channel.

The block insulating film 35 is an insulating layer that prevents charge stored in the charge storage film 34 from spreading to the wiring layer 23. The block insulating film 35 is a film containing, for example, metal and oxygen, such as an aluminum oxide film.

The block insulating film 35 may have a multilayered structure including a layer containing a material having a higher dielectric constant than silicon oxide. As the high dielectric constant material, for example, silicon nitride can be used.

In the pillar MP shown in FIG. 7, a portion of the wiring layer 22 crosses the pillar MP and functions as the select transistor ST2. Portions where the pillar MP and the wiring layers 23 cross each other function as the memory cell transistors MT0 to MT7. A portion of the wiring layer 24 crosses a pillar MP3 and functions as the select transistor ST1.

The top surface of the semiconductor film 31 in the pillar MP has the columnar contact CV. In the area shown in FIG. 7, two contacts CV corresponding to the respective two pillars MP among the six pillars MP are shown. To the pillars MP that do not overlap the slit portions SHE and are unconnected to the contacts CV in the area, another contacts CV are connected in an area not shown in the drawing.

One of the wiring layers 25, that is, one of the bit lines BL is in contact with the top surface of the contact CV. To the wiring layer 25, one of the contacts CV is connected in each space separated by the slit member SLT and the slit portion SHE. In other words, each of the wiring layers 25 is electrically connected to, for example, one of the pillars MP in each area between the slit member SLT and the slit portion SHE that are adjacent to each other, and one of the pillars MP in each area between two adjacent slit portions SHE.

The slit member SLT is formed to extend, for example, along an XZ plane. The slit members SLT penetrate the wiring layers 22 to 24 and the insulator layers 41 to 44. For example, the slit members SLT increase in width in the Y direction from the bottom to the top.

In the slit member SLT, the contact LI is provided to extend along an XZ plane, and the spacer SP is provided between the contact LI and the wiring layers 22 to 24 and the insulator layers 41 to 45. The upper end of the contact LI is located in, for example, the insulator layer 45. The lower end of the contact LI is in contact with, for example, the wiring layer 21. Note that the contact LI may be omitted depending on the structure of the memory cell array 10.

The slit portions SHE are formed like plates extending along an XZ plane and divide the wiring layer 24. The upper ends of the slit portions SHE are located in the insulator layer 45. The lower ends of the slit portions SHE are located in, for example, the uppermost insulator layer 43. The slit portions SHE contain, for example, an insulator such as silicon oxide. Note that the upper ends of the slit portions SHE and the upper ends of the members SLT may be aligned or misaligned. Furthermore, the upper ends of the slit portions SHE and the upper ends of the pillars MP may be aligned or misaligned.

In the memory areas MA1 and MA2, the slit members SLT are formed like, for example, plates extending along an XZ plane and divide the wiring layers 22. For example, the upper end of the slit member SLT may be located at the boundary between the uppermost insulator layer 42 and the lowermost wiring layer 23 or may be located in the uppermost insulator layer 42. For example, the lower end of the slit member SLT may be located at the boundary between the wiring layer 21 and the insulator layer 41 or may be located in the insulator layer 41. In each of the memory areas MA1 and MA2, the slit member SLT is preferably provided at a position overlapping one of the slit portions SHE in the Z direction. The slit portions SHE contain, for example, an insulator such as silicon oxide. Note that the lower ends of the slit portions SHE and the lower ends of the slit members SLT may be aligned or misaligned.

1.1.5.3 Lead-out area

The outline of the planar layout of the lead-out area HA was described with reference to FIG. 5. Hereinafter, the structure of the lead-out area HA divided by the slit members SLTe and the surrounding structure will be described.

In the lead-out area HA shown in FIG. 9, the lead-out portion HP is provided for every two of the blocks BLK that are arranged in the Y direction and are adjacent to each other in the Y direction with the slit member SLTo interposed between the blocks BLK. In other words, in the lead-out area HA, the lead-out portion HP is divided into two by the slit members SLTe provided between two adjacent blocks BLK.

Hereinafter, one of the lead-out portions HP divided by the slit members SLTe will be referred to as a first lead-out portion HP1 and the other will be referred to as a second lead-out portion HP2 to discriminate between the lead-out portions. In FIG. 9, the lead-out portion HP illustrated above the slit members SLTe will be referred to as the first lead-out portion HP1. In FIG. 9, the lead-out portion HP illustrated below the slit members SLTe will be referred to as the second lead-out portion HP2.

The lead-out area HA includes the plurality of bridge portions BRG as described above. In the present embodiment, the bridge portion BRG is provided for each of the blocks BLK. In each of the bridge portions BRG, a portion provided in the memory area MA1 of each wiring layer of the stacked wiring and a portion provided in the memory area MA2 are connected to each other.

In the example shown in FIG. 9, the bridge portion BRG is located along a slit SLT0 extending on one end of the block BLK0 in the +Y direction. In the example shown in FIG. 9, the bridge portion BRG is located along a slit SLT0 extending on one end of the block BLK1 in the-Y direction.

In the example shown in FIG. 9, the direction of arranging the block BLK0 with respect to the block BLK1 is defined as the +Y direction while the direction of arranging the block BLK1 with respect to the block BLK0 is defined as the-Y direction. Moreover, the direction of arranging the memory area MA2 with respect to the lead-out area HA is defined as the +X direction while the direction of arranging the memory area MA1 with respect to the lead-out area HA is defined as the −X direction.

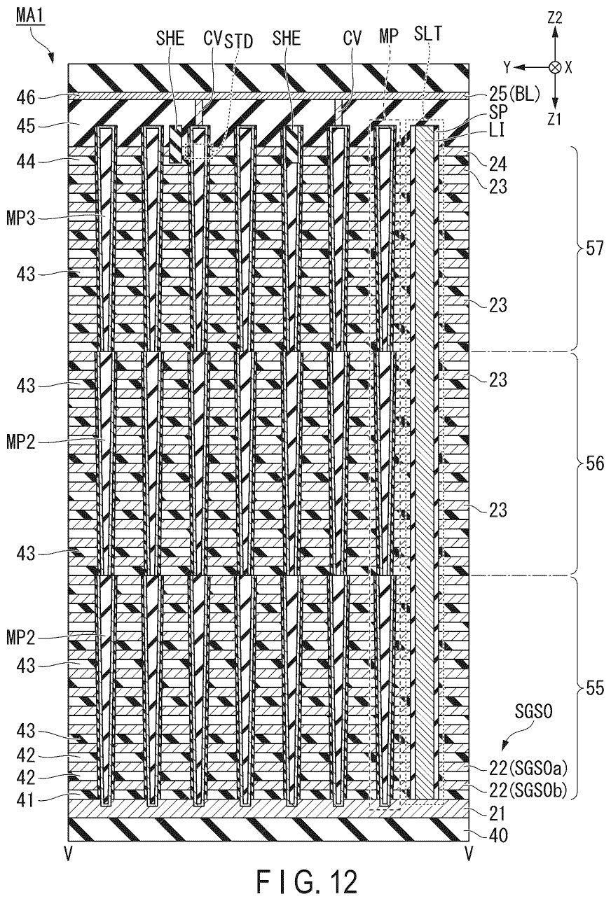

FIG. 10 shows the outline of the step area SSA formed in the lead-out portion HP and the outline of the connection state of the contacts CC connected to the step area SSA. Note that in FIG. 11A, the contacts CC connected to a tilted step portion SSAa and a tilted step portion SSAb are omitted.

When the lead-out portion HP1 is viewed in the Y direction from the slit member SLTe in the lead-out portion HP divided by the slit members SLTe, as described above, the first lead-out portion HP1 is shaped like a mountain having the tilted step portions on both sides.

As shown in FIGS. 9 to 11, in the first lead-out portion HP1, the wiring layers 22 and 23 have terrace portions that do not overlap the upper wiring layers 23 and the wiring layer 24. The shape of the terrace portion of the first lead-out portion HP1 is similar to a step, a terrace, a rimstone or the like. The contacts CC are connected to the terrace portions of the wiring layers 22 and 23.

The wiring layers 23 include the tilted step portions SSAa and SSAb in the first lead-out portion HP1. The tilted step portions SSAa and SSAb are steps including the ends of the sequentially stacked wiring layers 23 that are provided in rectangular shapes in plan view. In the tilted step portions SSAa and SSAb, the ends of the sequentially stacked wiring layers 23 tilt at nearly the same tilt angle in a diagonal direction in an XZ plane and a YZ plane, and the tilted step portions SSAa and SSAb form slopes.

Each of the wiring layers 23 includes a portion provided in the memory area MA1 and a portion provided in the memory area MA2 such that the portions are electrically connected to each other via portions provided for the bridge portions BRG in the lead-out area HA. That is, the same wiring layer 23 has an equal potential regardless of the portion.

In the block BLK0, an area that is interposed between the slit member SLT0 and the slit member SLTe and is adjacent to the bridge portion BRG has two recess portions RE1 and RE2 with the bottoms gradually decreasing in height. The recess portions RE1 and RE2 are adjacent to each other in the X direction.

In the block BLK1, an area that is interposed between the slit member SLT0 and the slit member SLTe and is adjacent to the bridge portion BRG has two recess portions RE3 and RE4 with the bottoms gradually decreasing in height. The recess portions RE3 and RE4 are adjacent to each other in the X direction.

An area RE1a at the lowest position in the recess portion RE1 is formed in an area at the position close to the slit member SLTe and the memory area MA1. The area RE1a at the lowest position in the recess portion RE1 is formed like a rectangle in plan view in FIG. 9.

With respect to the area RE1a, rectangular areas RE1b, RE1c, RE1d, RE1e, RE1f, and RE1g are formed so as to gradually increase in size in the +X direction and the +Y direction in plan view. The set of the areas RE1b, RE1c, RE1d, RE1e, RE1f, and RE1g forms the bottom of the recess portion RE1.

The areas RE1a, RE1b, RE1c, RE1d, RE1e, RE1f, and RE1g are partially arranged stepwise along the slit member SLTe in the X direction, which form the tilted step portion SSAa.

An area RE2a at the lowest position in the recess portion RE2 is formed in an area at the position close to the slit member SLTe and the memory area MA2. The area RE2a at the lowest position in the recess portion RE2 is formed like a rectangle in plan view in FIG. 9.

With respect to the area RE2a, rectangular areas RE2b, RE2c, RE2d, RE2e, RE2f, and RE2g are formed so as to gradually increase in size in the −X direction and the +Y direction in plan view. The set of the areas RE2b, RE2c, RE2d, RE2e, RE2f, and RE2g forms the bottom of the recess portion RE2.

The areas RE2a, RE2b, RE2c, RE2d, RE2e, RE2f, and RE2g are partially arranged stepwise along the slit member SLTe in the X direction, which form the tilted step portion SSAb.

As described above, the tilted step portion SSAa and the tilted step portion SSAb are arranged along the X direction. Thus, as shown in the cross section of FIG. 11A, the tilted step portion SSAa and the tilted step portion SSAb are arranged in the shape of a mountain in side view.

FIG. 11A is a cross-sectional view taken along line XIA-XIA of FIG. 9, and FIG. 11B is a cross-sectional view taken line XIB-XIB of FIG. 9. FIG. 11A shows a cross section at the boundary position between the slit member SLTe and the first lead-out portion HP1 and the second lead-out portion HP2. Thus, FIG. 11A illustrates the tilted step portion SSAa and the tilted step portion SSAb are arranged in the shape of a mountain. FIG. 11B shows a cross section taken along line XIB-XIB passing through the center of the slit member SLTe in the width direction. Thus, FIG. 11B illustrates the tilted step portion SSAa and the tilted step portion SSAb hidden behind an insulating layer are indicated by chain lines.

The contacts CC are connected to the steps of the tilted step portion SSAa formed on the −X direction side of the block BLK0 shown in FIG. 9. As an example, on the tilted step portion SSAa, the first contact CC from the left end corresponds to the select gate line SGS0b. The second contact CC from the left end corresponds to the select gate line SGS0a. The third contact CC from the left end corresponds to the word line WL4. The fourth contact CC from the left end corresponds to the word line WL5. The fifth contact CC from the left end corresponds to the word line WL6. The sixth contact CC from the left end corresponds to the word line WL7. In FIG. 9, types of lines to be connected are denoted by parenthesized reference numerals at the positions of the corresponding contacts CC of the first lead-out portion HP1.

The first contact CC from the left end corresponds to the word line WL3 in the tilted step portion SSAb formed on the +X direction side of the block BLK0 shown in FIG. 9. The second contact CC from the left end corresponds to the word line WL2. The third contact CC from the left end corresponds to the word line WL1. The fourth contact CC from the left end corresponds to the word line WL0. The fifth contact CC from the left end corresponds to the select gate line SGS1a. The sixth contact CC from the left end corresponds to the select gate line SGS1b.

Note that the contacts CC connected to the tilted step portion SSAa and the tilted step portion SSAb of the block BLK0 have different types of lines to be connected. Thus, the area RE1a at the lowest position of the tilted step portion SSAa and the area RE2a at the lowest position of the tilted step portion SSAb shown in FIG. 9 are formed at different height positions in the Z direction. Likewise, the areas RE1b to RE1g of the tilted step portion SSAa are also formed at different height positions with respect to the areas RE2b to RE2g of the tilted step portion SSAb and are connected to different types of lines via the respective contacts CC.

In the lead-out portion HP divided by the slit members SLTe, the second lead-out portion HP2 also has the tilted step portion SSAa and the tilted step portion SSAb like the first lead-out portion HP1. The contacts CC are connected to the steps of the tilted step portion SSAa and the tilted step portion SSAb.

With respect to the recess portion RE1 formed in the block BLK0, the recess portion RE3 formed in the block BLK1 has line symmetry in shape in plan view while the center line of the slit member SLTe serves as the axis. With respect to the recess portion RE2 formed in the block BLK0, the recess portion RE4 formed in the block BLK1 has line symmetry in shape in plan view while the slit member SLTe serves as the axis.

The area RE3a at the lowest position in the recess portion RE3 is illustrated like a rectangle in plan view in FIG. 9. With respect to the area RE3a, rectangular areas RE3b, RE3c, RE3d, RE3e, RE3f, and RE3g are formed so as to gradually increase in size in the +X direction and the-Y direction in plan view.

The set of the areas RE3b, RE3c, RE3d, RE3e, RE3f, and RE3g forms the bottom of the recess portion RE3. The areas RE3a, RE3b, RE3c, RE3d, RE3e, RE3f, and RE3g are partially arranged stepwise along the slit member SLTe in the X direction, which form the step area SSAa in the block BLK1.

An area RE4a at the lowest position in the recess portion RE4 is illustrated like a rectangle in plan view in FIG. 9. With respect to the area RE4a, rectangular areas RE4b, RE4c, RE4d, RE4e, RE4f, and RE4g are formed so as to gradually increase in size in the −X direction and the −Y direction in plan view.

The set of the areas RE4b, RE4c, RE4d, RE4e, RE4f, and RE4g forms the bottom of the recess portion RE4. The areas RE4a, RE4b, RE4c, RE4d, RE4e, RE4f, and RE4g are arranged stepwise along the slit member SLTe in the X direction, which form the tilted step portion SSAb in the block BLK1.

Also in the second lead-out portion HP2, the contacts CC are disposed on the steps of the tilted step portion as in the first lead-out portion HP1. As an example, the types of lines corresponding to the contacts CC will be described below sequentially from the left end of the tilted step portion SSAa on the left side of the second lead-out portion HP2 of FIG. 9.

The contact CC corresponding to the word line WL7, the contact CC corresponding to the word line WL6, the contact CC corresponding to the word line WL5, the contact CC corresponding to the word line WL4, the contact CC corresponding to the select gate line SGS0a, the contact CC corresponding to the select gate line SGS0b.

In the tilted step portion SSAb on the right side of the second lead-out portion HP2 shown in FIG. 9, the following is described sequentially from the left end.

The contact CC corresponding to the select gate line SGS1b, the contact CC corresponding to the select gate line SGS1a, the contact CC corresponding to the word line WL0, the contact CC corresponding to the word line WL1, the contact CC corresponding to the word line WL2, the contact CC corresponding to the word line WL3.

The contacts CC connected to the tilted step portion SSAa and the tilted step portion SSAb of the block BLK1 have different types of lines to be connected. Hence, the areas RE1a to RE1g of the tilted step portion SSAa of the block BLK1 are also formed at different height positions with respect to the areas RE2a to RE2g of the tilted step portion SSAb of the block BLK1 and are connected to different types of lines via the respective contacts CC.

It can be conceived that the lead-out area HA is provided between the memory areas MA1 and MA2 in the planar layout shown in FIG. 9.

It is assumed that the memory area MA1 has a structure in which the wiring layers 23 (first conductive layers) 23 are stacked in the first direction and the pillars MP penetrate the stacked wiring layers 23. Thus, the memory area MA1 can be referred to as a first area that includes the wiring layers (first conductive layers) 23 stacked at certain intervals in the first direction and the pillars (semiconductor pillars) MP extending in the first direction in the wiring layers 23 and has memory cells formed at the intersections between the wiring layers 23 and the pillars MP.

The memory area MA2 can be referred to as a second area that includes the wiring layers (second conductive layers) 23 stacked at certain intervals in the first direction and the pillars (semiconductor pillars) MP extending in the first direction in the wiring layers 23 and has memory cells formed at the intersections between the wiring layers 23 and the pillars MP. The first area and the second area are separated from each other in the X direction different from the stacking direction of the wiring layers 23.

Moreover, the lead-out area HA is disposed with the wiring layers (third conductive layers) 23 stacked at certain intervals between the memory area (first area) MA1 and the memory area (second area) MA2 in the second direction crossing the first direction. Furthermore, one of the wiring layers 23 includes the lead-out portion HP that connects to one of the wiring layers (first conductive layers) 23 of the memory area MA1 and one of the wiring layers (second conductive layers) 23 of the memory area MA2. The lead-out area HA can be referred to as a third area.

The lead-out area HA includes the bridge portion (fourth area) BRG in which one of the wiring layers (third conductive layers) 23 electrically connects one of the first conductive layers and one of the second conductive layers, and the step area (fifth area) SSA in which one of the wiring layers (third conductive layers) 23 is connected to the contact CC. The tilted step area SSA includes the tilted step portions SSAa and SSAb where the wiring layers (third conductive layers) 23 are partially stacked stepwise.

In the present embodiment, the slit member SLTe that divides the first lead-out portion HP1 and the second lead-out portion HP2 shown in FIG. 9 has a characteristic structure.

The slit member SLTe has an intermittent portion 36 in the end-side area of the lead-out area HA in the vicinity of the memory area MA2. The slit member SLTe has the intermittent portion 36 located between the area RE2a at the lowest position of the recess portion RE2 and the area RE4a at the lowest position of the recess portion RE4.

The intermittent portion 36 is formed in an area close to the end of the tilted step portion SSAb in the +X direction.

The slit member SLTe has an intermittent portion 37 in the end-side area of the lead-out area HA in the vicinity of the memory area MA1. The slit member SLTe has the intermittent portion 37 located between the area RE1a at the lowest position of the recess portion RE1 and the area RE3a at the lowest position of the recess portion RE3.

In the slit member SLTe, the intermittent portion 37 is provided at a position close to the end of the lead-out area HA in the −X direction. Alternatively, the intermittent portion 37 may be displayed in the end-side area of the lead-out area HA in the vicinity of the memory area MA1.

The intermittent portion 36 is a portion except for the spacers SP and the contact LI that constitute the slit member SLTe. The intermittent portion 37 is a portion except for the spacers SP and the contact LI that constitute the slit member SLTe. Furthermore, the intermittent portion 36 is filled with a bridging portion (filling layer) 38, and the intermittent portion 37 is filled with a bridging portion (filling layer) 39. The bridging portions 38 and 39 contain silicon oxide. The bridging portions 38 and 39 are located on both sides of the slit member SLTe in the Y direction and are provided to bridge between the insulting layers provided to bury the tilted step portions SSAa and SSAb.

FIG. 11A shows a side view of the first lead-out portion HP1 shaped like a mountain with the tilted step portion SSAa and the tilted step portion SSAb on both oblique sides. FIG. 11A shows the positions of the bridging portions 38 and 39 in areas at the base of the mountain-like first lead-out portion HP1 in side view. In FIG. 11A, the contacts CC are omitted and the tilted step portion SSAa and the tilted step portion SSAb are mainly shown.

Note that a comparison between FIGS. 11A and 11B and FIG. 9 shows that the tilted step portions SSAa and SSAb are hidden behind the slit member SLTe in a cross-sectional view at the position of the slit member SLTe and the intermittent portions 36 and 37.

As shown in FIG. 11A, the bridging portions 38 and 39 are located on both sides of the mountain-like first lead-out portion HP1 in the X direction in side view. Moreover, the bridging portions 38 and 39 are formed like protrusions extending in the Z direction from the underside of the lowermost layer to the top surface of the uppermost layer of the first lead-out portion HP1 shaped like a mountain in side view. In other words, the bridging portion 38 is formed from the areas RE2a and RE4a at the lowest position in the recess portions RE2 and RE4 to the height of the uppermost portions of the recess portions RE2 and RE4. The bridging portion 39 is formed from the areas RE1a and RE3a at the lowest position in the recess portions RE1 and RE3 to the height of the uppermost portions of the recess portions RE1 and RE3. The lowermost layers of the bridging portions 38 and 39 are formed in or on a partial area of the step area (fifth area) SSA in which the tilted step portions SSAa and SSAb are not formed. As shown in FIG. 11A, the bridging portions 38 and 39 have larger widths in the extending direction of the slit member (X-direction width) in the bridging portions 38 and 39 on the upper layer side than in the extending direction of the slit member (X-direction width) in the bridging portions 38 and 39 on the lower layer side.

In the form shown in FIG. 11A, the sectional widths of the bridging portions 38 and 39 along an XY plane decrease gradually from the ends in the Z1 direction toward the ends in the Z2 direction.

As shown in FIG. 9, the lead-out area HA is formed between the memory area MA1 and the memory area MA2. The bridging portion 38 is disposed along a location near the memory area MA2 in the recess portions RE2 and RE4 formed in the lead-out area HA, and the bridging portion 39 is disposed along a location near the memory area MA1 in the recess portions RE1 and RE3.

An insulator layer 50 is formed on the tilted step portion SSAb. The insulator layer 50 is formed to fill the recess portions RE1, RE2, RE3, and RE4.

FIG. 11A is a cross section taken along line XIA-XIA of FIG. 9 and thus shows the insulator layer 50 filling the recess portions RE1 and RE3. FIG. 11B is a cross section taken along line XIB-XIB of FIG. 9 and thus shows a cross section of the layers constituting the slit member SLTe.

The insulator layer 43 formed between the wiring layers 23 in the memory area MA1 can be referred to as a first insulator layer. The insulator layer 43 formed between the wiring layers 23 in the memory area MA2 can be referred to as a second insulator layer. The insulator layer 43 formed between the wiring layers 23 in the lead-out area HP can be referred to as a third insulator layer. The insulator layer 50 formed on the tilted step portions SSAa and SSAb in the lead-out area HA can be referred to as a fourth insulator layer.

As shown in FIG. 9, the slit member SLTe is disposed to divide the tilted step portions SSAa and SSAb of the block BLK0 and the tilted step portions SSAa and SSAb of the block BLK1, into two in plan view. The slit member SLTe extends along the extending direction of the steps of the tilted step portions SSAa and SSAb (step arrangement direction: X direction).

As viewed in this manner, it may indicate that the slit member SLTe divides the tilted step portions SSAa and SSAb of the block BLK0 and the tilted step portions SSAa and SSAb of the block BLK1 in the step width direction (Y direction) of the tilted step portions SSAa and SSAb.

A method for manufacturing the lead-out portion will be described below.

A stacked body is formed such that a plurality of sacrificial layers, which are not shown, and a plurality of insulating layers are stacked on a semiconductor substrate that is not shown. The stacked insulating layers are insulating layers that serve as the insulator layers 41, 42, 43, and 44 in the memory areas MA1 and MA2. The insulator layer 43 in the memory area MA1 can be referred to as a first insulator layer, the insulator layer 43 in the memory area MA2 can be referred to as a second insulator layer, and the insulator layer 43 in the lead-out area HP can be referred to as a third insulator layer.

The stacked body is etched to provide the tilted step portions SSAa and SSAb. The tilted step portions SSAa and SSAb are filled with the insulator layer. The insulator layer can be referred to as a fourth insulator layer. A groove-shaped slit is formed to cross the tilted step portions SSAa and SSAb at a position corresponding to the slit member SLTe that is linearly shaped in plan view as shown in FIG. 9. In this configuration, when cut portions are formed in the linear slit, the insulator layer at the cut portions serves as the bridging portions 38 and 39. The sacrificial layers are dissolved by an etching solution through the groove-shaped slit and then are removed. Thereafter, conductive layers are formed in portions where the sacrificial layers have been removed. This forms the tilted step portions SSAa and SSAb in which the wiring layers 23 (or the wiring layers 22 and 24) and the insulator layers 43 (or 41, 42, 44) are stacked. At this point, the lowermost portions of the bridging portions 38 and 39 are located at the same height as the lowermost portion of the lowermost conductive layer 23 or are located at a lower position.

The conductive layers formed on the side walls and bottom of the groove-shaped slit are removed by etching. The spacers SP are formed inside the slit member SLTe. The contact LI is formed inside the spacers SP, so that the slit members SLTe are formed. The contact LI may be a conductor, an insulator, or a semiconductor. For example, the contact LI may be made of a metal such as tungsten, an oxide such as SiO₂, a nitride such as SiN, or a conductor containing Si or Ge.

When the insulator layer 50 is formed on the tilted step portions SSAa and SSAb, the bridging portions 38 and 39 can be formed at cut portions in the slit groove. The slit member SLT divides the unit area (block BLK) including the memory area MA1 (first area), the memory area MA2 (second area), and the lead-out area HA (third area). The insulator layer 50 is formed on both sides of the slit members SLTe in the width direction. Thus, the intermittent portions 36 and 37 formed in the slit member SLTe are formed to communicate with the step area (fifth area), and the bridging portions 38 and 39 connect the insulator layer 50 on both sides of the slit member SLTe in the width direction.

### 1.2 Effects of First Embodiment

According to the first embodiment, the insulator layer 50 is formed on the tilted step portions SSAa and SSAb. In addition, the bridging portion 39 is formed at a position adjacent to the tilted step portion SSAa, and the insulator layer 50 is formed around the bridging portion 39. The bridging portion 38 is formed at a position adjacent to the tilted step portion SSAb, and the insulator layer 50 is formed around the bridging portion 38.

The bridging portions 38 and 39 are formed as portions of the slit member SLTe that divides the lead-out portion HP into the first lead-out portion HP1 and the second lead-out portion HP2. Furthermore, the structure is provided such that the lead-out portion HP is formed over the plurality of blocks BLK and the lead-out portion HP is divided by the slit member SLTe.

As described above, the structure including the bridging portions 38 and 39 can obtain the following effects.

In the structure of the present embodiment, the tilted step portions SSAa and SSAb are provided to connect the wiring layers 22 and 23 of the memory areas MA1 and MA2. The slit member SLTo passes through the stacked body of the wiring layers 23 and the insulator layers 43 that are formed in the memory areas MA1 and MA2. In contrast, the slit member SLTe passes through the stacked body of the wiring layers 23 and the insulator layers 43 that are formed in the memory areas MA1 and MA2, and passes through the lead-out area HA so as to divide the lead-out portion HP of the mountain-like stacked structure.

In order to form the slit member SLTo and the slit member SLTe that pass through the different processing areas, it is necessary to form groove-shaped slits corresponding to the different processing areas and then embed the spacers SP and the contact LI so as to fill the slits.

However, a difference among the processing areas may cause imbalance in processing on a portion that divides the lead-out portion HP of the mountain-like stacked structure and the surrounding portion, so that the ends of the stacked structure formed in the memory areas MA1 and MA2 may be deformed near the lead-out area HA. For example, after the slit is formed, the slit is filled with a material constituting the spacers SP and the contact LI. When heat is applied by heat treatment or the like in a downstream process, a stress is applied to the film and causes deformation.

For example, in semiconductor storages having finer circuits under present circumstances, deformation of about several nm to several tens nm may occur.

In contrast, in the structure shown in FIGS. 9 to 11, the bridging portions 38 and 39 are provided on portions of the slit member SLTe. The bridging portions 38 and 39 are formed by leaving the insulating layer in the slit formation area when the groove-shaped slit is formed as the basis of the slit member SLTe. In other words, after the formation of the stacked structure as the basis of the memory areas MA1 and MA2 and the stacked structure as the basis of the tilted step portions SSAa and SSAb, the insulator layer is formed on the stacked structure serving as the basis of the tilted step portions SSAa and SSAb. In addition, when a slit is formed on the insulator layer to form the slit member SLTe, portions of the insulator layer are intermittently left without forming a continuous slit entirely in the X direction, so that the bridging portions 38 and 39 are formed.

In the semiconductor storage 3, after the stacked body of the insulator layers 42 and 43 and the sacrificial layers is formed in the memory areas MA1 and MA2, the process of forming a memory hole and depositing a block insulating film, a tunnel insulating film, a charge storage film, and a core film or the like is performed, and then the process of replacing the sacrificial layer with a metal layer to fabricate a memory cell transistor is performed. When the sacrificial layer is replaced with a metal layer, the sacrificial layer is replaced using the groove-shaped slit for forming the slit member.

Thus, when heat treatment is performed after the basic structure of the memory cell transistor MT is formed, heat treatment is performed while the slit is not filled. Also in the lead-out area HA, heat is applied while the slit is not filled. Thus, the stacked structure as the basis of the tilted step portions SSAa and SSAb may be deformed by heat or the ends of the stacked structure formed in the memory areas MA1 and MA2 may be deformed by heat near the lead-out area HA.

However, the foregoing structure includes the bridging portions 38 and 39 at this stage, and thus deformation is less likely to occur in the presence of the bridging portions 38 and 39. Thus, as a stacked structure serving as the basis of the tilted step portions SSAa and SSAb, a well-formed structure can be obtained without deformation. Moreover, a well-formed structure can be obtained in which the ends of the stacked structure formed in the memory areas MA1 and MA2 are not deformed near the lead-out area HA.

The embodiment shown in FIGS. 7 to 11 described an example in which the bridging portions 38 and 39 are provided in a structure including only one layer of the stacked body including the stacked wiring layers 23 and insulator layers 43 and the pillars MP passing through the stacked layers in the Z direction.

For the stacked body including the stacked wiring layers 23 and insulator layers 43 and the pillars MP passing through the stacked layers in the Z direction, any number of times of stacking, for example, two or more times of stacking can be performed.

The shape of the tilted step portions SSAa and SSAb in the plan view shown in FIG. 9 is merely an example, and the tilted step portions SSAa and SSAb are not limited to the shape of this example. The planar shapes of the recess portions RE1 to RE4 for forming the tilted step portions SSAa and SSAb shown in FIG. 9 are not limited to rectangles. Any shape can be adopted if the tilted step portions SSAa and SSAb can be formed in the shape.

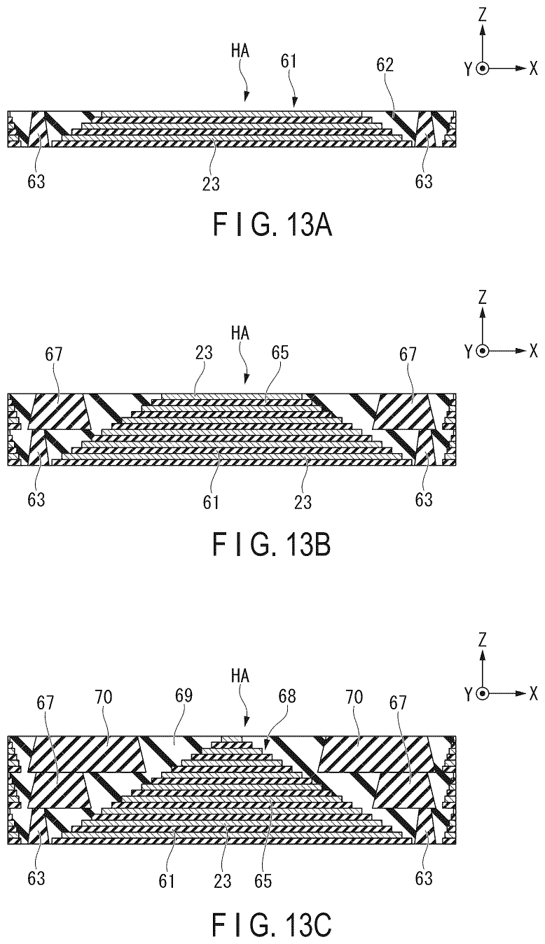

FIG. 12 shows an example of a structure in which stacked bodies are provided in three layers, the stacked body including the stacked wiring layers 23 and insulator layers 43 and the pillars MP passing through the stacked layers in the Z direction.

FIG. 12 shows a structure in which a first stacked body 55 is provided near the insulator layer 40, the first stacked body 55 including the stacked wiring layers 23 and insulator layers 43 and first pillars (first semiconductor pillars) MP1 passing through the stacked layers in the Z direction. Formed on the first stacked body 55 is a second stacked body 56 including the stacked wiring layers 23 and insulator layers 43 and second pillars (second semiconductor pillars) MP2 passing through the stacked layers in the Z direction. Formed on the second stacked body 56 is a third stacked body 57 including the stacked wiring layers 23 and insulator layers 43 and third pillars (third semiconductor pillars) MP3 passing through the stacked layers in the Z direction.

Since other structures are identical to those of the first embodiment, an explanation thereof is omitted and the same components are denoted by the same reference numerals.

For the structure including the stacked body having the three-layer structure in FIG. 12, the structure including the bridging portions of the foregoing embodiment can be applied.

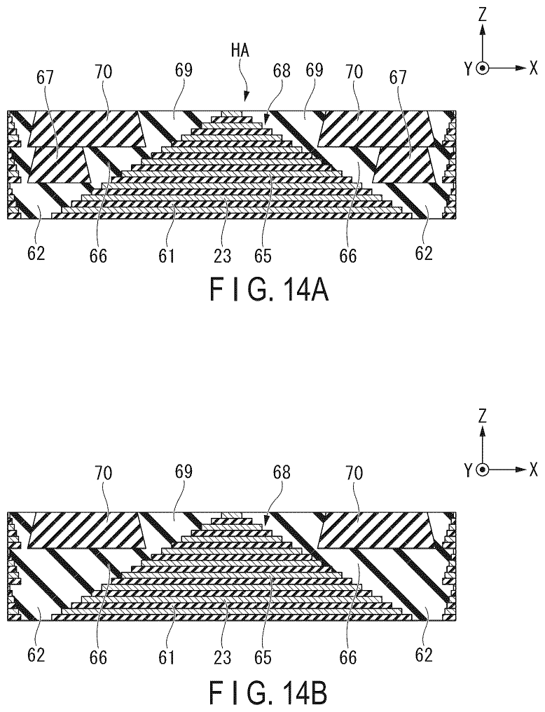

FIGS. 13A to 13C are explanatory drawings showing the outline of the manufacturing process for the structure including the bridging portions of the foregoing embodiment in the lead-out area having a three-layer structure that corresponds to the stacked body of the memory area having a three-layer structure.

For the simplicity of illustration, the following drawings are described as schematic explanatory drawings in which the wiring layers and the insulator layers that constitute the stacked body are small in number.

As shown in FIG. 13A, a first stacked body 61 is formed with a tilted step portion including a predetermined number of stacked insulating layers and sacrificial layers. An insulator layer 62 is formed on the tilted step portion of the first stacked body 61. Thereafter, a slit groove is formed by etching a portion corresponding to the slit member SLTe in FIG. 9. A portion having no slit grooves serves as a first bridging portion 63 on the left and right sides of the first stacked body 61 in the X direction. The slit groove is filled with a sacrificial layer different from the sacrificial layer included in the first stacked body 61.

As shown in FIG. 13B, on the first stacked body 61, a second stacked body 65 is formed with a tilted step portion including a predetermined number of stacked insulating layers and sacrificial layers. An insulator layer 66 is formed on the tilted step portion of the second stacked body 65. Thereafter, a slit groove is formed by etching a portion corresponding to the slit member SLTe in FIG. 9. A portion having no slit grooves serves as a second bridging portion 67 formed on the left and right sides of the second stacked body 65 in the X direction. The slit groove is filled with a sacrificial layer different from the sacrificial layers included in the first stacked body 61 and the second stacked body 65. The sacrificial layer filling the slit groove may be the same as the sacrificial layers included in the first stacked body 61 and the second stacked body 65.

In this example, the width of the second bridging portion 67 in the X direction is larger than the width of the first bridging portion 63 in the X direction. The width of the second bridging portion 67 can be increased by seamlessly connecting the slopes of the tilted step portion of the first stacked body 61 and the tilted step portion of the second stacked body 65 and increasing the width of an area between the slopes and the adjacent memory area MA1 or MA2 in the X direction. In other words, the width of the second bridging portion 67 in the extending direction in the X direction is larger than the width of the first bridging portion 63 in the extending direction in the X direction.

As shown in FIG. 13C, on the second stacked body 65, a third stacked body 68 is formed with a tilted step portion including a predetermined number of stacked insulating layers and sacrificial layers. An insulator layer 69 is formed on the tilted step portion of the third stacked body 68. Thereafter, a slit groove is formed by etching a portion corresponding to the slit member SLTe in FIG. 9. A portion having no slit grooves serves as a third bridging portion 70 formed on the left and right sides of the third stacked body 68 in the X direction.

In this example, the width of the third bridging portion 70 in the X direction is larger than the width of the second bridging portion 67 in the X direction. The width of the third bridging portion 70 can be increased by seamlessly connecting the slopes of the tilted step portion of the second stacked body 65 and the tilted step portion of the third stacked body 68 and increasing the width of an area between the slopes and the adjacent memory area MA1 or MA2 in the X direction. In other words, the width of the third bridging portion 70 in the extending direction in the X direction is larger than the width of the second bridging portion 67 in the extending direction in the X direction.

Thereafter, the sacrificial layer filling the slit grooves formed in the first stacked body 61 and the second stacked body 65 is removed. Thereafter, the sacrificial layers alternately stacked with the insulating layers of the first stacked body 61, the second stacked body 65, and the third stacked body 68 are replaced with conductive layers.

In the structure shown in FIG. 13C, the first bridging portion 63 is provided on the left and right sides of the first stacked body 61, the second bridging portion 67 is provided on the left and right sides of the second stacked body 65, and the third bridging portion 70 is provided on the left and right sides of the third stacked body 68.

Thus, according to the structure shown in FIG. 13C, deformation is less likely to occur on the ends of the layers of stacked bodies 61, 65, and 68 near the memory areas and the ends of the layers of the memory areas near the lead-out area HA.

Hence, as a stacked structure serving as the basis of the tilted step portions SSAa and SSAb, a well-formed structure can be obtained without deformation like the structure shown in FIGS. 9 to 11. Moreover, a well-formed stacked structure can be obtained such that the ends of the stacked structure formed in the memory areas MA1 and MA2 are not deformed near the lead-out area HA.

### (Second Embodiment)

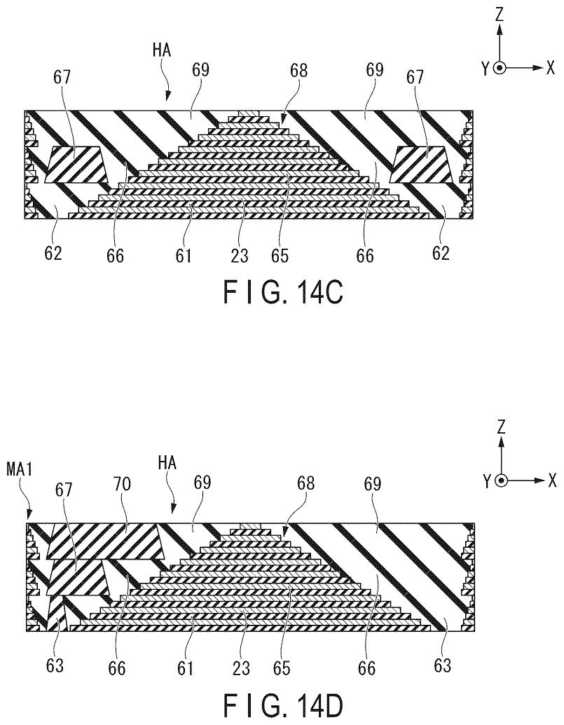

FIG. 14A shows a second embodiment in a structure including bridging portions for a lead-out area having a three-layer structure.

In the structure shown in FIG. 14A, the first bridging portion 63 provided in the structure shown in FIG. 13C is omitted and an insulator layer 62 is formed also at the position of the bridging portion 63.

Also in this structure, bridging portions 67 and 70 are provided, thereby achieving the function of preventing deformation as in the structure shown in FIG. 13C.

In other words, deformation is less likely to occur on the ends of the layers of stacked bodies 65 and 68 near the memory areas and the ends of the layers of the memory areas near a lead-out area HA.

Thus, as a stacked structure serving as the basis of tilted step portions SSAa and SSAb, a well-formed structure can be obtained without deformation. Moreover, a well-formed stacked structure can be obtained such that the ends of the stacked structure formed in memory areas MA1 and MA2 are not deformed near the lead-out area HA.

### (Third Embodiment)

FIG. 14B shows a third embodiment in a structure including a bridging portion for a lead-out area having a three-layer structure.

In the structure shown in FIG. 14B, the bridging portions 63 and 67 provided in the structure shown in FIG. 13C are omitted and insulator layers 62 and 66 are formed also at the positions of the bridging portions 63 and 67.

Also in this structure, a bridging portion 70 is provided, thereby achieving the function of preventing deformation as in the structure shown in FIG. 13C.

In other words, deformation is less likely to occur on the ends of the layers of a stacked body 68 near the memory areas and the ends of the layers of the memory areas near a lead-out area HA.

Thus, as a stacked structure serving as the basis of tilted step portions SSAa and SSAb, a well-formed structure can be obtained without deformation. Moreover, a well-formed stacked structure can be obtained such that the ends of the stacked structure formed in memory areas MA1 and MA2 are not deformed near the lead-out area HA.

### (Fourth Embodiment)

FIG. 14C shows a fourth embodiment in a structure including a bridging portion for a lead-out area having a three-layer structure.

In the structure shown in FIG. 14C, the bridging portions 63 and 70 provided in the structure shown in FIG. 13C are omitted and insulator layers 62 and 69 are formed also at the positions of the bridging portions 63 and 70.

Also in this structure, a bridging portion 67 is provided, thereby achieving the function of preventing deformation as in the structure shown in FIG. 13C.

In other words, deformation is less likely to occur on the ends of the layers of a stacked body 65 near the memory areas and the ends of the layers of the memory areas near a lead-out area HA.

Thus, as a stacked structure serving as the basis of tilted step portions SSAa and SSAb, a well-formed structure can be obtained without deformation. Moreover, a well-formed stacked structure can be obtained such that the ends of the stacked structure formed in memory areas MA1 and MA2 are not deformed near the lead-out area HA.

### (Fifth Embodiment)

FIG. 14D shows a fifth embodiment in a structure including bridging portions for a lead-out area having a three-layer structure.

In the structure shown in FIG. 14D, the bridging portions 63, 67, and 70 are omitted on the +X direction side of the stacked bodies 61, 65, and 68 provided in the structure shown in FIG. 13C and insulator layers 62, 66, and 69 are formed also at the positions of the bridging portions 63, 67, and 70 on the +X direction side.

Also in this structure, the bridging portions 63, 67, and 70 are provided on the-X direction side of the stacked bodies 61, 65, and 68, thereby achieving the function of preventing deformation as in the structure shown in FIG. 13C.

In other words, deformation is less likely to occur on the ends of the layers of the stacked bodies 61, 65, and 68 near a memory area MA1 and the ends of the layers of the memory area MA1 near a lead-out area HA.

Thus, as a stacked structure serving as the basis of tilted step portions SSAa and SSAb, a well-formed structure can be obtained without deformation. Moreover, a well-formed stacked structure can be obtained such that the ends of the stacked structure formed in the memory area MA1 are not deformed near the lead-out area HA.

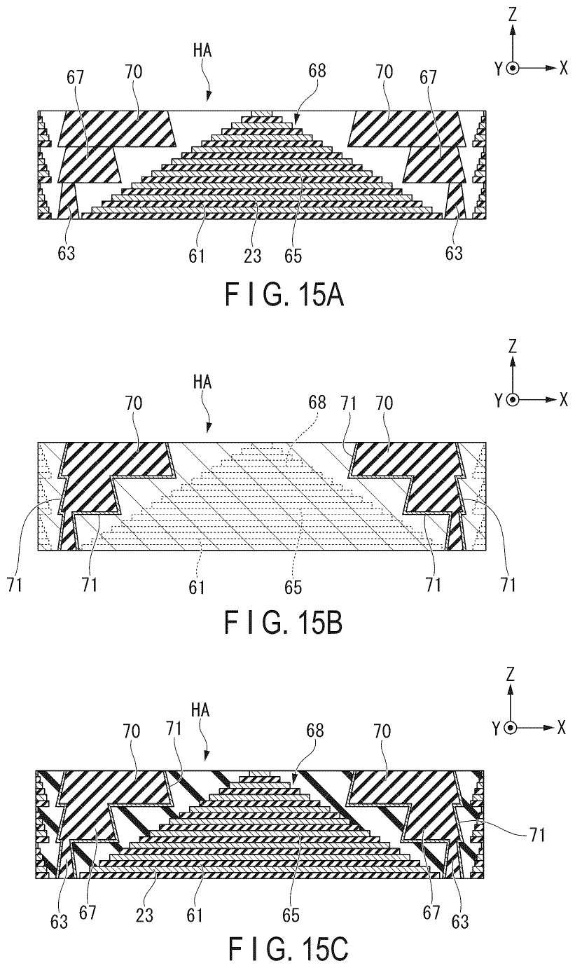

FIGS. 15A to 15C are explanatory drawings showing a manufacturing method in the order of steps for a structure similar to that shown in FIG. 13C, in which the bridging portions are provided in a lead-out area HA having a three-layer structure.

The outline of the manufacturing method of the structure shown in FIG. 13C has been described above.

As in the state of FIG. 13C, FIG. 15A shows a state in which a first stacked body 61, a first bridging portion 63, and an insulator layer 62 are formed, a second stacked body 65, a second bridging portion 67, and an insulator layer 66 are formed, a third stacked body 68, a third bridging portion 70, and an insulator layer 69 are formed, and then the insulator layers 69, 66, and 62 are removed from the stacked body. FIG. 15A shows a state in which three layers of slits are formed as a basis for forming slit members and the insulator layers filling the slits are removed.

After the groove-shaped slits are formed, in the stacked structure of insulator layers 43 and sacrificial layers that are formed in memory areas MA1 and MA2, a memory cell transistor is configured by depositing a block insulating film, a tunnel insulating film, a charge storage film, and a core film or the like in a memory hole in which pillars are to be formed.

When a material that forms the block insulating film is an aluminum oxide, an aluminum oxide film is formed, and then films made of materials constituting the tunnel insulating film, the charge storage film, and the core film are deposited thereon.

Thus, also in the structure shown in FIG. 15A in which the insulator layer filling the inside of the slit is removed, the block insulating film, the tunnel insulating film, the charge storage film, and the core film or the like are deposited. The block insulating film, the tunnel insulating film, the charge storage film, and the core film that are formed in the memory hole are necessary and thus are left, whereas the film formed in the slit is unnecessary and thus is removed.

However, even if etching means for removing the tunnel insulating film, the charge storage film, and the core film is used, the aluminum oxide film for the block insulating film remains without being removed.

Therefore, a coating 71 of aluminum oxide remains at the bottoms and sides of the first bridging portion 63, the second bridging portion 67, and the third bridging portion 70 that are left after the insulator layer is removed. FIGS. 15B and 15C show the coating 71 of an aluminum oxide film formed at the bottoms and sides of the first bridging portion 63, the second bridging portion 67, and the third bridging portion 70. Note that FIG. 15B is a cross-sectional view showing that the inside of the slit is filled with a film for forming a memory cell transistor and thus a tilted step portion is present behind the film.

After the removal of the tunnel insulating film, the charge storage film, and a material layer for the core film that are formed in the slit, spacers SP and a contact LI fill the inside of the slit to complete the structure shown in FIG. 15C.

Also in the structure shown in FIG. 15C, the bridging portions 63, 67, and 70 are provided on both sides of the stacked bodies 61, 65, and 68 in the X direction, thereby achieving the function of preventing deformation as in the structure shown in FIG. 13C.

In other words, deformation is less likely to occur on the ends of the layers of the stacked bodies 61, 65, and 68 near the memory area MA1 and the ends of the layers of the memory area MA1 near the lead-out area HA. In addition, deformation is less likely to occur on the ends of the layers of the stacked bodies 61, 65, and 68 near the memory area MA2 and the ends of the layers of the memory area MA2 near the lead-out area HA.

Thus, as a stacked structure serving as the basis of tilted step portions SSAa and SSAb, a well-formed structure can be obtained without deformation. Moreover, a well-formed stacked structure can be obtained such that the ends of the stacked structure formed in memory areas MA1 and MA2 are not deformed near the lead-out area HA.

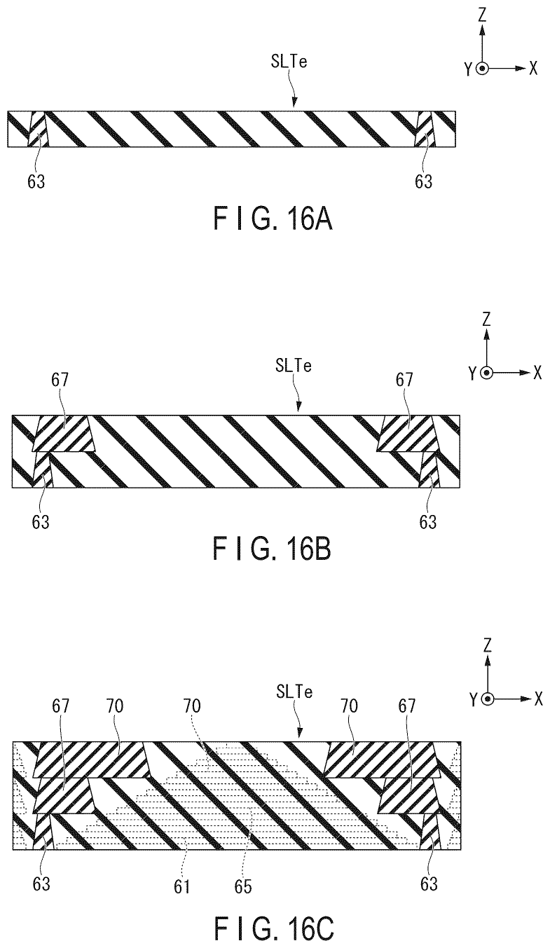

FIGS. 16A to 16C are explanatory cross-sectional views corresponding to the steps of manufacturing the stacked body having a three-layer structure as shown in FIGS. 13A to 13C. The cross-sectional view shows the formation side of the tilted step portion along a cutting plane at the center of the slit member SLTe in the width direction. As described above, in FIGS. 13A to 13C, the bridging portions and the tilted step portions are displayed on the same plane to facilitate recognition of the relative positions of the first bridging portion 63, the second bridging portion 67, and the third bridging portion 70 with respect to the tilted step portions.

In reality, as shown in FIG. 9, the slit member SLTe and the lead-out portion HP1 are formed while being displaced from each other in the Y direction. Thus, as shown in FIGS. 16A and 16B, a layer for configuring the slit member is provided between the left and right first bridging portions 63 and between the left and right second bridging portions 67. In FIGS. 16A to 16C, the relationship is illustrated.

### (Sixth Embodiment)

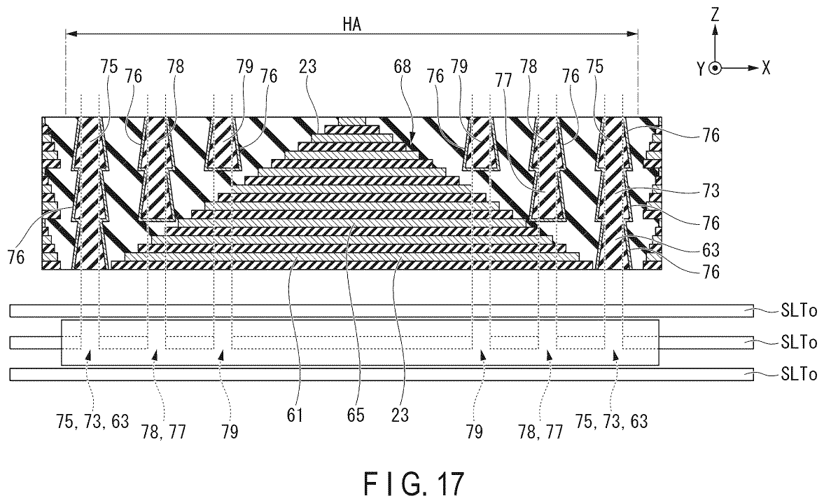

FIG. 17 is an explanatory drawing showing a sixth embodiment of a stacked structure including tilted step portions and bridging portions that are formed in a lead-out area HA. FIG. 17 shows both of a plan view of the layout of the lead-out area HA and memory areas MA1 and MA2 and a cross-sectional view of the lead-out area HA and the memory areas MA1 and MA2.

In FIG. 17, a slit member SLT0 and a slit member SLTe are simplified as single-layer structures. In the structure shown in FIG. 17, the configuration of the tilted step portion and the structures of the memory areas MA1 and MA2 are identical to the structure shown in FIG. 13C or the structure shown in FIG. 15C.

The structure shown in FIG. 17 is different from the structures shown in FIGS. 13C and 15C in the structures of bridging portions. The structure of a first bridging portion 63 is identical to that provided in the first stacked body 61 in the structures shown in FIGS. 13C and 15C. In the structure shown in FIG. 17, a second bridging portion 73 is formed on the left and right sides of a second stacked body 65 in the X direction such that the second bridging portion 73 is connected onto the first bridging portion 63. A third bridging portion 75 is formed on the left and right sides of a third stacked body 68 in the X direction such that the third bridging portion 75 is connected onto the second bridging portion 73.

The first bridging portion 63, the second bridging portion 73, and the third bridging portion 75 are continuously formed into a single bridging portion in the Z direction. On the sides of the first bridging portion 63, the second bridging portion 73, and the third bridging portion 75, a coating 76 equivalent to the coating 71 of aluminum oxide described with reference to FIG. 15C is formed.

In the structure shown in FIG. 17, a second bridging portion 77 is formed at a position closer to the tilted step portion of the second stacked body 65 than the second bridging portion 73 while being separated from the tilted step portion. The structure of the second bridging portion 77 has the same shape as the second bridging portion 73 but is formed at a different position.

In the structure shown in FIG. 17, a third bridging portion 78 is formed on the left and right sides of the third stacked body 68 in the X direction such that the third bridging portion 78 is connected onto the second bridging portion 77.

A third bridging portion 79 is formed at a position closer to the tilted step portion of the third stacked body 68 than the third bridging portion 78 while being separated from the tilted step portion. The structure of the third bridging portion 79 has the same shape as the second bridging portion 77 but is formed at a different position.

According to the structure of the sixth embodiment shown in FIG. 17, the bridging portions 75, 78, and 79 or the bridging portions 73 and 77 are provided in the extending direction (Z direction) of the slit member SLTe. Also in the structure including the bridging portions in the extending direction (Z direction) of the slit member SLTe, the function of preventing deformation can be achieved as in the structure shown in FIG. 13C.

In other words, deformation is less likely to occur on the ends of the layers of the stacked bodies 61, 65, and 68 near the memory area MA1 and the ends of the layers of the memory area MA1 near the lead-out area HA. In addition, deformation is less likely to occur on the ends of the layers of the stacked bodies 61, 65, and 68 near the memory area MA2 and the ends of the layers of the memory area MA2 near the lead-out area HA.

Thus, as a stacked structure serving as the basis of tilted step portions SSAa and SSAb, a well-formed structure can be obtained without deformation. Moreover, a well-formed stacked structure can be obtained such that the ends of the stacked structure formed in memory areas MA1 and MA2 are not deformed near the lead-out area HA.

### (Seventh Embodiment)

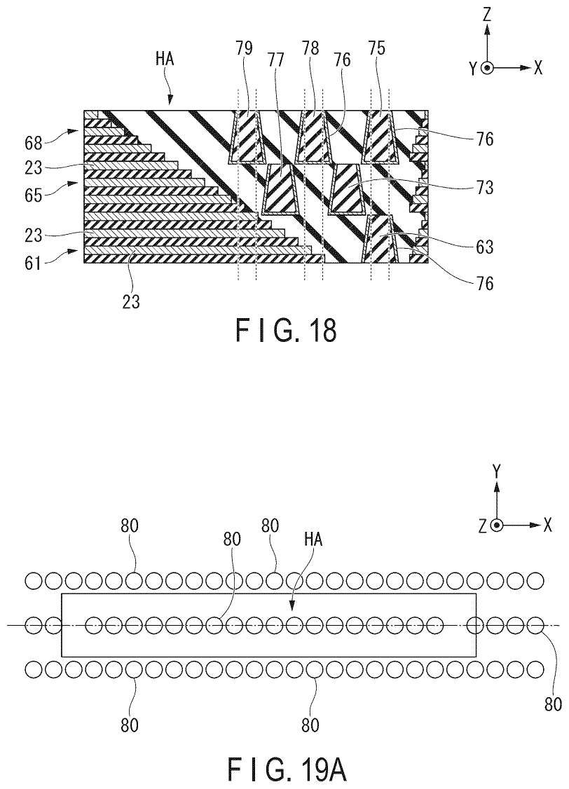

FIG. 18 is an explanatory drawing showing a seventh embodiment of a stacked structure including tilted step portions and bridging portions that are formed in a lead-out area HA. FIG. 18 shows both of a plan view of the layout of the lead-out area HA and memory areas MA1 and MA2 and a cross-sectional view of the lead-out area HA and the memory areas MA1 and MA2.

In the structure shown in FIG. 18, the configuration of the tilted step portion and the structures of the memory areas MA1 and MA2 are identical to the structure shown in FIG. 13C or the structure shown in FIG. 15C.

Also in the structure shown in FIG. 18, a first bridging portion 63 is provided as in the structure shown in FIG. 17. In addition, second bridging portions 73 and 77 are provided and third bridging portions 75, 78, and 79 are provided. In the structure shown in FIG. 17, the first bridging portion 63, the second bridging portion 73, and the third bridging portion 75 are continuously formed into a single bridging portion in the Z direction. In contrast, in the structure shown in FIG. 18, the first bridging portion 63 and the third bridging portion 75 are disposed in the Z direction but the second bridging portion 73 is displaced from the first bridging portion 63 and the third bridging portion 75 in the-X direction. In the structure shown in FIG. 18, the second bridging portion 77 is displaced from the third bridging portion 78 in the-X direction.

Also when the bridging portions are arranged in a staggered manner in the X direction as shown in FIG. 18, the function of preventing deformation of the stacked structure is achieved as in the foregoing embodiments.

### (Eighth Embodiment)

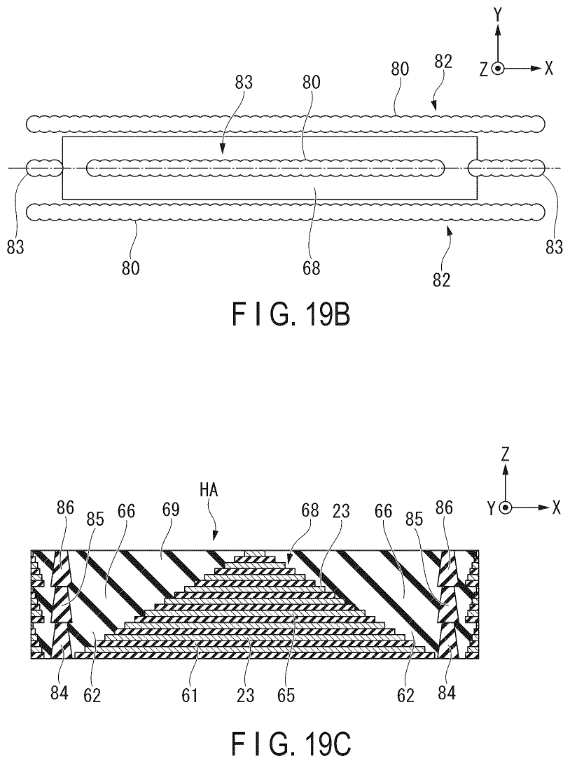

FIGS. 19A to 19C are explanatory drawings showing a manufacturing method in the order of steps for a structure similar to that shown in FIG. 11, in which the bridging portions are provided in a lead-out area HA.

FIG. 19A shows a slit member SLTe formed in a groove slit having the same width in the structure shown in FIG. 11.

In contrast, in the structure of the eighth embodiment, a slit is composed of a set of holes. Holes 80 are arranged with a diameter equivalent to a width corresponding to the groove slit in which the slit member SLTe is formed. The holes 80 are formed linearly at predetermined intervals along the X direction while being aligned with the position of the slit member SLTe. In other words, the holes 80 are formed by etching linearly at predetermined intervals along the X direction while being aligned with the position of a slit member SLTo. Alternatively, the holes 80 may be formed linearly to slightly overlap one another. The holes 80 and holes for forming memory pillars MP may be formed by similar etching.

FIG. 19A shows a planar layout in this state. Note that the holes 80 are not formed at positions where first bridging portions 63 are to be formed.

Next, the holes 80 are connected in the X direction by further etching between the adjacent holes 80 as shown in FIG. 19B. This forms a slit with the connected holes 80.

The slit member SLTo can be formed by filling a slit 82 with a material for forming the slit member SLTo, the slit 82 being formed at a position where the slit member SLTo is to be disposed.

The slit member SLTe can be formed by filling a slit 83 with a material for forming the slit member SLTe, the slit 83 being formed at a position where the slit member SLTe is to be disposed.

Thereafter, by performing the step of forming the memory cell transistor and other necessary steps as in the steps described with reference to FIGS. 15A to 15C or the like, a structure including a first bridging portion 84, a second bridging portion 85, and a third bridging portion 86 can be obtained as in a cross-sectional structure shown in FIG. 19C.

Also in the structure shown in FIG. 19C, the function of preventing deformation of the stacked structure can be achieved as in the foregoing embodiments.

### (Ninth Embodiment)

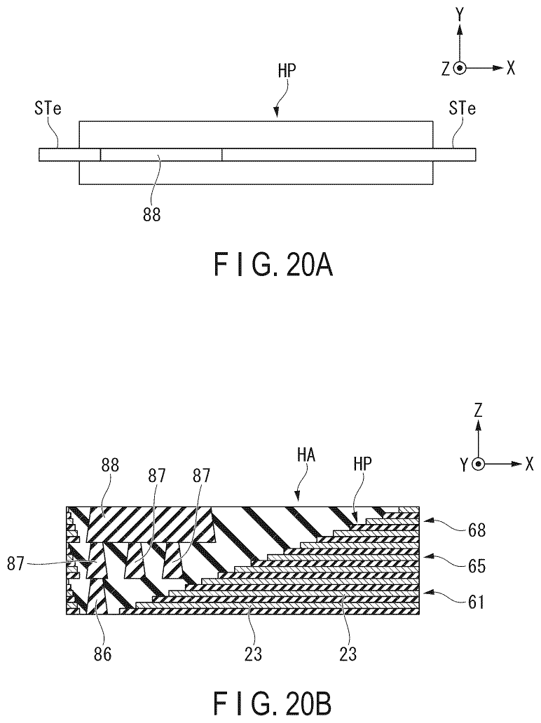

FIGS. 20A and 20B show the structure of a ninth embodiment in which bridging portions are provided for a lead-out area HP having a three-layer structure. The structure including a first bridging portion 63 for a first stacked body 61 is identical to those of the foregoing embodiments. In the present embodiment, three second bridging portions 87 are formed in a second stacked body 65 while being spaced in the X direction. Furthermore, in a third stacked body 68, a third bridging portion 88 having a larger width than three second bridging portions 87 in the X direction is formed, the second bridging portions 87 being formed in the second stacked body 65 while being spaced along the X direction.

As described in the eighth embodiment, the widths of the first bridging portion 63, the second bridging portion 87, and the third bridging portion 88 in the X direction are not particularly limited. Any widths can be selected for the first bridging portion 63, the second bridging portion 87, and the third bridging portion 88 in the X direction if the bridging portions are not in contact with the first stacked body 61, the second stacked body 65, and the third stacked body 68 and are not in contact with the memory area MA1 around the bridging portions.

In other words, any widths can be selected for the first bridging portion 63, the second bridging portion 87, and the third bridging portion 88 in the extending direction of the slit member SLT.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. The accompanying claims and their equivalents are intended to cover such forms or modification as would fall within the scope and spirit of the inventions.

What is claimed is

1. A semiconductor storage, comprising:
a first area that includes a plurality of first conductive layers stacked at predetermined intervals in a first direction and first semiconductor pillars extending in the first direction in the plurality of first conductive layers and has memory cells formed at intersections between the plurality of first conductive layers and the first semiconductor pillars;
a second area that includes a plurality of second conductive layers stacked at predetermined intervals and second semiconductor pillars extending in the first direction in the plurality of second conductive layers and has memory cells formed at intersections between the plurality of second conductive layers and the second semiconductor pillars; and
a third area that includes a plurality of third conductive layers stacked at predetermined intervals such that the third area is disposed between the first area and the second area and one of the third conductive layers connects to one of the first conductive layers and one of the second conductive layers,
wherein the third area includes a fourth area in which one of the third conductive layers electrically connects one of the first conductive layers and one of the second conductive layers, and a fifth area in which one of the third conductive layers is connected to a contact, the fifth area including a tilted step portion where the third conductive layers are partially stacked stepwise,
a plurality of unit areas are provided, each of the unit areas including the first area, the second area, and the third area,
a plurality of slit members are provided, the slit members dividing the unit areas into individual areas,
among the plurality of slit members, one of the slit members is adjacent to the fifth area, and
the one of the slit members include intermittent adjacent to the fifth area, and include bridging portions filling the intermittent portions.

2. The semiconductor storage of claim 1, wherein:
the first semiconductor pillar and the second semiconductor pillar each include a block insulating film, a charge storage film, and a semiconductor film, and
a coating made of the same material as the block insulating film is on a side or a bottom of the bridging portion.

3. The semiconductor storage of claim 2, further comprising:
a sixth area that includes a plurality of fourth conductive layers stacked at predetermined intervals in the first direction and third semiconductor pillars extending in the first direction in the plurality of fourth conductive layers and has memory cells formed at intersections between the plurality of fourth conductive layers and the third semiconductor pillars;
a seventh area that includes a plurality of fifth conductive layers stacked at predetermined intervals and fourth semiconductor pillars extending in the first direction in the plurality of fifth conductive layers and has memory cells formed at intersections between the plurality of fifth conductive layers and the fourth semiconductor pillars; and
an eighth area that includes a plurality of sixth conductive layers stacked at predetermined intervals such that the eighth area is between the sixth area and the seventh area and one of the sixth conductive layers connects to one of the fourth conductive layers and one of the fifth conductive layers,
wherein the eighth area includes a ninth area in which one of the sixth conductive layers electrically connects one of the fourth conductive layers and one of the fifth conductive layers, and a tenth area in which one of the sixth conductive layers is connected to a contact, the tenth area including a tilted step portion where the sixth conductive layers are partially stacked stepwise,
wherein the intermittent portions are between the fifth portion and the tenth portion.

4. The semiconductor storage of claim 1, wherein:
the bridging portion contains silicon oxide, and
the bridging portion has a height from a lowermost layer to an uppermost layer of the tilted step portion.

5. The semiconductor storage of claim 1, wherein the bridging portion has a lowermost layer on a partial area of the fifth area in which the tilted step portion is not formed.

6. The semiconductor storage of claim 2, wherein the bridging portion has a lowermost layer on a partial area of the fifth area in which the tilted step portion is not formed.

7. The semiconductor storage of claim 3, wherein the bridging portion has a lowermost layer on a partial area of the fifth area in which the tilted step portion is not formed.

8. The semiconductor storage of claim 4, wherein the bridging portion has a lowermost layer on a partial area of the fifth area in which the tilted step portion is not formed.

9. The semiconductor storage of claim 1, wherein:
the first area has a stacked structure including a plurality of first stacked bodies that are stacked in the first direction, each of the first stacked bodies including the plurality of first conductive layers and first semiconductor pillars extending through the plurality of first conductive layers in the first direction,
the second area has a stacked structure including a plurality of second stacked bodies that are stacked in the first direction, each of the second stacked bodies including the plurality of second conductive layers and second semiconductor pillars extending through the plurality of second conductive layers in the first direction, and
the third area has a stacked structure including conductive layers corresponding to the first stacked body and the second stacked body.

10. The semiconductor storage of claim 2, wherein:
the first area has a stacked structure including a plurality of first stacked bodies that are stacked in the first direction, each of the first stacked bodies including the plurality of first conductive layers and first semiconductor pillars extending through the plurality of first conductive layers in the first direction,
the second area has a stacked structure including a plurality of second stacked bodies that are stacked in the first direction, each of the second stacked bodies including the plurality of second conductive layers and second semiconductor pillars extending through the plurality of second conductive layers in the first direction, and
the third area has a stacked structure including conductive layers corresponding to the first stacked body and the second stacked body.

11. The semiconductor storage of claim 3, wherein:
the first area has a stacked structure including a plurality of first stacked bodies that are stacked in the first direction, each of the first stacked bodies including the plurality of first conductive layers and first semiconductor pillars extending through the plurality of first conductive layers in the first direction,
the second area has a stacked structure including a plurality of second stacked bodies that are stacked in the first direction, each of the second stacked bodies including the plurality of second conductive layers and second semiconductor pillars extending through the plurality of second conductive layers in the first direction, and
the third area has a stacked structure including conductive layers corresponding to the first stacked body and the second stacked body.

12. The semiconductor storage of claim 4, wherein:
the first area has a stacked structure including a plurality of first stacked bodies that are stacked in the first direction, each of the first stacked bodies including the plurality of first conductive layers and first semiconductor pillars extending through the plurality of first conductive layers in the first direction,
the second area has a stacked structure including a plurality of second stacked bodies that are stacked in the first direction, each of the second stacked bodies including the plurality of second conductive layers and second semiconductor pillars extending through the plurality of second conductive layers in the first direction, and
the third area has a stacked structure including conductive layers corresponding to the first stacked body and the second stacked body.

13. The semiconductor storage of claim 1, wherein:
the first area has a stacked structure including a plurality of first stacked bodies that are stacked in the first direction, each of the first stacked bodies including the plurality of first conductive layers and first semiconductor pillars extending through the plurality of first conductive layers in the first direction,
the second area has a stacked structure including a plurality of second stacked bodies that are stacked in the first direction, each of the second stacked bodies including the plurality of second conductive layers and second semiconductor pillars extending through the plurality of second conductive layers in the first direction,
the third area has a stacked structure including conductive layers corresponding to the first stacked body and the second stacked body, and
the bridging portion has a stacked structure having a height corresponding to a height of the first stacked body and the second stacked body in a stacking direction, and the bridging portion has a larger width in an extending direction of the slit member in the bridging portion on an upper layer side than in the extending direction of the slit member in the bridging portion on a lower layer side.

14. The semiconductor storage of claim 2, wherein:
the first area has a stacked structure including a plurality of first stacked bodies that are stacked in the first direction, each of the first stacked bodies including the plurality of first conductive layers and first semiconductor pillars extending through the plurality of first conductive layers in the first direction,
the second area has a stacked structure including a plurality of second stacked bodies that are stacked in the first direction, each of the second stacked bodies including the plurality of second conductive layers and second semiconductor pillars extending through the plurality of second conductive layers in the first direction,
the third area has a stacked structure including conductive layers corresponding to the first stacked body and the second stacked body, and
the bridging portion has a stacked structure having a height corresponding to a height of the first stacked body and the second stacked body in a stacking direction, and the bridging portion has a larger width in an extending direction of the slit member in the bridging portion on an upper layer side than in the extending direction of the slit member in the bridging portion on a lower layer side.

15. The semiconductor storage of claim 3, wherein:
the first area has a stacked structure including a plurality of first stacked bodies that are stacked in the first direction, each of the first stacked bodies including the plurality of first conductive layers and first semiconductor pillars extending through the plurality of first conductive layers in the first direction,
the second area has a stacked structure including a plurality of second stacked bodies that are stacked in the first direction, each of the second stacked bodies including the plurality of second conductive layers and second semiconductor pillars extending through the plurality of second conductive layers in the first direction,
the third area has a stacked structure including conductive layers corresponding to the first stacked body and the second stacked body, and
the bridging portion has a stacked structure having a height corresponding to a height of the first stacked body and the second stacked body in a stacking direction, and the bridging portion has a larger width in an extending direction of the slit member in the bridging portion on an upper layer side than in the extending direction of the slit member in the bridging portion on a lower layer side.

16. The semiconductor storage of claim 4, wherein:
the first area has a stacked structure including a plurality of first stacked bodies that are stacked in the first direction, each of the first stacked bodies including the plurality of first conductive layers and first semiconductor pillars extending through the plurality of first conductive layers in the first direction,
the second area has a stacked structure including a plurality of second stacked bodies that are stacked in the first direction, each of the second stacked bodies including the plurality of second conductive layers and second semiconductor pillars extending through the plurality of second conductive layers in the first direction,
the third area has a stacked structure including conductive layers corresponding to the first stacked body and the second stacked body, and
the bridging portion has a stacked structure having a height corresponding to a height of the first stacked body and the second stacked body in a stacking direction, and the bridging portion has a larger width in an extending direction of the slit member in the bridging portion on an upper layer side than in the extending direction of the slit member in the bridging portion on a lower layer side.

17. A method for manufacturing a semiconductor storage comprising a first area that includes a plurality of first conductive layers stacked via first insulator layers and first semiconductor pillars penetrating the plurality of first conductive layers and has memory cells formed at intersections between the first conductive layers and the first semiconductor pillars; a second area that includes a plurality of second conductive layers stacked via second insulator layers and second semiconductor pillars penetrating the plurality of second conductive layers and has memory cells formed at intersections between the second conductive layers and the second semiconductor pillars, the second area being separated from the first area in a direction different from a stacking direction;
and a third area that includes a plurality of third conductive layers stacked via third insulator layers and is disposed between the first area and the second area, wherein a tilted step portion is formed in a part of the third area such that the third conductive layers are partially arranged stepwise, a contact is connected to the tilted step portion, a slit member having an intermittent portion corresponding to a part of the tilted step portion is provided, the slit member extending in a step arrangement direction of the tilted step portion and dividing the tilted step portion in a step width direction, and the tilted step portion is covered with a fourth insulator layer, the method comprising:
stacking a plurality of sacrificial layers and the plurality of first insulator layers in the first area, stacking a plurality of sacrificial layers and the plurality of second insulator layers in the second area, stacking a plurality of sacrificial layers and the plurality of third insulator layers in the third area, forming the tilted step portion by etching on the third area, and filling the tilted step portion with a fourth insulator layer;
forming a groove-shaped slit that divides the tilted step portion along an extending direction of the tilted step portion in a width direction of the tilted step portion and has the intermittent portions, and forming bridging portions composed of the fourth insulator layer at the intermittent portions by the formation of the slit; and
after dissolving and removing the plurality of sacrificial layers of the third area through the slit, forming the plurality of third conductive layers at positions of the plurality of sacrificial layers of the third area.

18. The method for manufacturing a semiconductor storage of claim 17, further comprising forming a spacer and a contact in the groove-shaped slit to fill the groove-shaped slit.

19. The method for manufacturing a semiconductor storage of claim 17, wherein the sacrificial layers are dissolved by an etching solution through the slit and then are removed.

20. The method for manufacturing a semiconductor storage of claim 18, wherein the bridging portion has a lowermost portion located at a lower position than a lowermost portion of the plurality of third conductive layers.
